(19) United States
(12) Patent Application Publication
(10) Pub. No.: US 2026/0116740 A1
(43) Pub. Date: Apr. 30, 2026

(54) DIELECTRIC STACK FOR MICROELECTROMECHANICAL SYSTEM DEVICES AND METHODS OF FABRICATION THEREOF

(71) Applicant: Texas Instruments Incorporated, Dallas, TX (US)

(72) Inventors: Kelly J. Taylor, Allen, TX (US); Jose A. Martinez, Murphy, TX (US); Earl V. Atnip, Plano, TX (US); Jessie Yuan, Dallas, TX (US); Christopher Beard, Allen, TX (US)

(21) Appl. No.: 19/282,270

(22) Filed: Jul. 28, 2025

Related U.S. Application Data
(60) Provisional application No. 63/712,855, filed on Oct. 28, 2024.

(51) Int. Cl. B81B 7/00; B81C 1/00

(52) U.S. Cl. CPC B81B 7/0067; B81C 1/00317; B81B 2201/042; B81B 2203/0118; B81B 2203/0163; B81B 2203/04; B81B 2207/07; B81C 2201/0132; B81C 2201/0147; B81C 2201/0181; B81C 2201/0197; B81C 2201/0198

(57) ABSTRACT

A device includes one or more layers of a microelectromechanical system (MEMS) structure and a dielectric stack over the one or more layers. The dielectric stack includes a first dielectric layer having a first index of refraction, and a second dielectric layer having a second index of refraction different than the first index of refraction.

### CROSS-REFERENCE TO RELATED APPLICATIONS

This Application claims the benefit of and priority to U.S. Provisional Patent Application Ser. No. 63/712,855 (Texas Instruments Docket No. T105616US01), filed on Oct. 28, 2024, which Application is hereby incorporated herein by reference in its entirety.

### TECHNICAL FIELD

The present disclosure relates to the field of electromechanical devices, such as microelectromechanical system (MEMS) devices, and methods of fabricating the same.

### BACKGROUND

MEMS devices typically include integrated circuitry or other microelectronic elements along with micromechanical elements controlled by or otherwise interacting with the microelectronic elements. Such micromechanical and microelectronic elements typically have dimensions at or above a micrometer (μm) scale, e.g., microscale dimensions. The micromechanical elements can be formed utilizing photolithography, material deposition, etching and/or other fabrication processes which may be the same as or similar to those used for forming the associated microelectronic elements. Moreover, MEMS devices have many applications and thus, by way of example only, can serve as temperature sensors, pressure sensors, accelerometers, microswitches, micromirrors, spatial light modulators, phase light modulators, and micro-fluidic devices.

### SUMMARY

The present disclosure describes MEMS devices with dielectric stacks and methods of fabrication thereof. This summary is not an extensive overview of the disclosure. Rather, a purpose of the summary is to present some examples of the present disclosure in a simplified form as a prelude to a more detailed description that is presented later.

In some examples, a device includes one or more layers of a MEMS structure and a dielectric stack over the one or more layers. The dielectric stack includes a first dielectric layer having a first index of refraction, and a second dielectric layer having a second index of refraction different than the first index of refraction.

In some other examples, a device includes a MEMS substrate, a hinge over the MEMS substrate, a mirror structure supported by the hinge, and a dielectric stack over the mirror structure. The dielectric stack includes a first dielectric layer having a first index of refraction, and a second dielectric layer having a second index of refraction greater than the first index of refraction.

In some additional examples, a method of manufacturing a device includes forming a hinge on a MEMS substrate, forming a mirror structure on the hinge, and forming a dielectric stack on the mirror structure. The dielectric stack includes a first dielectric layer formed on a surface of the mirror structure, the first dielectric layer having a first index of refraction, and a second dielectric layer formed on the first dielectric layer, the second dielectric layer having a second index of refraction greater than the first index of refraction.

### BRIEF DESCRIPTION OF THE DRAWINGS

FIG. 1A is a cross-sectional view of a micromirror device with a dielectric stack in accordance with one or more examples of the present disclosure;

FIG. 1B is a graphical view illustrating increased reflectance caused by a micromirror device with a dielectric stack in accordance with one or more examples of the present disclosure;

FIG. 1C is a cross-sectional view of another micromirror device with a dielectric stack in accordance with one or more examples of the present disclosure;

FIG. 1D is a graphical view illustrating increased reflectance caused by a micromirror device with a dielectric stack in accordance with one or more examples of the present disclosure;

FIG. 1E is a graphical view illustrating reflectance caused by a micromirror device with dielectric stacks of different thicknesses in accordance with one or more examples of the present disclosure;

FIG. 2 is a cross-sectional view of a micromirror device with a dielectric stack and an alloy layer in accordance with one or more examples of the present disclosure;

FIG. 3 is a flow diagram of a methodology for forming a MEMS device with a dielectric stack in accordance with one or more examples of the present disclosure;

FIGS. 4A-4O are cross-sectional views of a process flow for forming a micromirror structure in accordance with one or more examples of the present disclosure;

FIG. 5 is a three-dimensional view of a MEMS device with which one or more examples of the present disclosure may be implemented;

FIG. 6 is a three-dimensional view of a MEMS device configured as a single spring tip pixel with which one or more examples of the present disclosure may be implemented;

FIG. 7 is a three-dimensional view of a MEMS device configured as a tilt and roll pixel with which one or more examples of the present disclosure may be implemented;

FIG. 8 is a three-dimensional view of a MEMS device configured as a dual spring tip pixel with which one or more examples of the present disclosure may be implemented;

FIGS. 9A and 9B are respective three-dimensional and cross-sectional views of a MEMS device configured as a phase light modulator with which one or more examples of the present disclosure may be implemented;

FIG. 10 is a three-dimensional view of another MEMS device configured as a phase light modulator with which one or more examples of the present disclosure may be implemented;

FIGS. 11A and 11B are respective three-dimensional and cross-sectional views of a micromirror device in accordance with one or more examples of the present disclosure;

FIG. 12 is a block diagram of a projection system with a spatial light modulator in accordance with one or more examples of the present disclosure;

FIG. 13 is a block diagram of a projection system with a phase light modulator in accordance with one or more examples of the present disclosure; and

FIG. 14 is a flow diagram of a methodology for fabricating a MEMS device in accordance with one or more examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

In some figures, devices are illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While MEMS devices have wide ranging applications, micromirrors as well as other MEMS devices that process light, have been used with increasing frequency in image projection and other optical applications. More particularly, micromirrors can be configured in an array and used to, for example, modulate light to create pixels of a projected image. Accordingly, device configurations that improve micromirror characteristics such as, for example, brightness, efficiency, and contrast are desirable technical goals. However, with the parallel goal of further miniaturizing MEMS devices, improving the above and other micromirror characteristics pose significant technical challenges.

Illustrative examples of the present disclosure overcome the above and other technical challenges by providing MEMS devices, such as micromirror devices, with dielectric stacks and/or other structural features that improve the above and other characteristics.

In some examples, a device includes one or more layers of a MEMS structure and a dielectric stack over the one or more layers. The dielectric stack includes a first dielectric layer having a first index of refraction, and a second dielectric layer having a second index of refraction different than the first index of refraction.

For example, the first dielectric layer can be positioned on one of the one or more layers, while the second dielectric layer can be positioned on the first dielectric layer. Thus, in some examples, the first index of refraction can be less than the second index of refraction. The first dielectric layer can include, in some examples, silicon oxide (e.g., SiO₂) and the second dielectric layer, in some examples, can include titanium oxide (e.g., TiO₂). In other examples, the first dielectric layer and the second dielectric layer are silicon nitride (e.g., SiN) films formed with different processing to achieve different refraction indices. Advantageously, as will be further described below, the addition of a dielectric stack with two dielectric materials having different indices of refraction on top of a micromirror device increases the reflectivity of the micromirror. By way of example, increased reflectivity results in improved thermal performance of the micromirror device due to less light absorption and thus less device heating.

In other examples, a third dielectric layer, e.g., including aluminum oxide (e.g., Al₂O₃), can be included on the dielectric stack. Advantageously, as will be further described below, the aluminum oxide layer provides, for example, protection of the dielectric stack by preventing or otherwise reducing moisture absorption by the micromirror device, and preventing or otherwise reducing micromirror stress and shape changes. The aluminum oxide layer may also prevent reactivity of the top layer of the dielectric stack, e.g., the TiO₂ layer. In other examples, the third dielectric layer is formed of silicon nitride (e.g., SiN).

Still further, in some examples, the device may include an alloy layer, e.g., including titanium aluminide (e.g., TiAl₃), positioned within the one or more layers of the MEMS structure. The material for the alloy layer may be selected to provide a desired or target net stress of the film stack. If different films or thicknesses are used for the dielectric layers of the dielectric stack, different materials may be selected for stress compensation and mirror shape tuning. Advantageously, as will be further described below, the titanium aluminide layer provides, for example, stress control to target specific micromirror shape and uniformity characteristics.

Accordingly, one or more of the example features enable stress tuning of the dielectric stack to control (e.g., optimize) mirror shape. Further, temperature stability according to one or more example features improves mirror stress and shape control.

In an example, the one or more layers of the MEMS structure include a substrate, a hinge over the substrate, and a mirror structure supported by the hinge. As such, the dielectric stack may be positioned on the mirror structure. In some examples, the mirror structure may be configurable to modulate a spatial attribute of a light beam, modulate a phase attribute of a light beam, and/or modulate some other characteristic of the light beam.

In some other examples, a device includes a MEMS substrate, a hinge over the MEMS substrate, a mirror structure supported by the hinge, and a dielectric stack over the mirror structure. The dielectric stack includes a first dielectric layer having a first index of refraction, and a second dielectric layer having a second index of refraction greater than the first index of refraction.

In some additional examples, a method of manufacturing a device includes forming a hinge on a MEMS substrate, forming a mirror structure on the hinge, and forming a dielectric stack on the mirror structure. The dielectric stack includes a first dielectric layer formed on a surface of the mirror structure, the first dielectric layer having a first index of refraction, and a second dielectric layer formed on the first dielectric layer, the second dielectric layer having a second index of refraction greater than the first index of refraction.

In some examples, the forming of the mirror structure and the forming of the dielectric stack may be performed at least in part during an integrated in-situ process. Advantageously, as will be further described below, the forming of the multiple layers of the dielectric stack on the mirror structure (e.g., micromirror) can be performed with a single pattern and etch process.

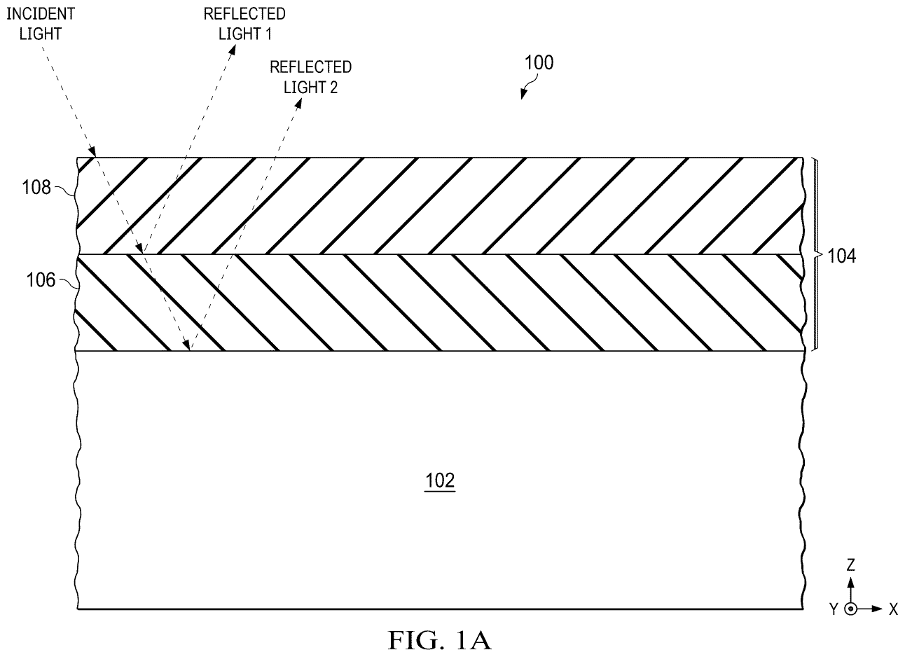

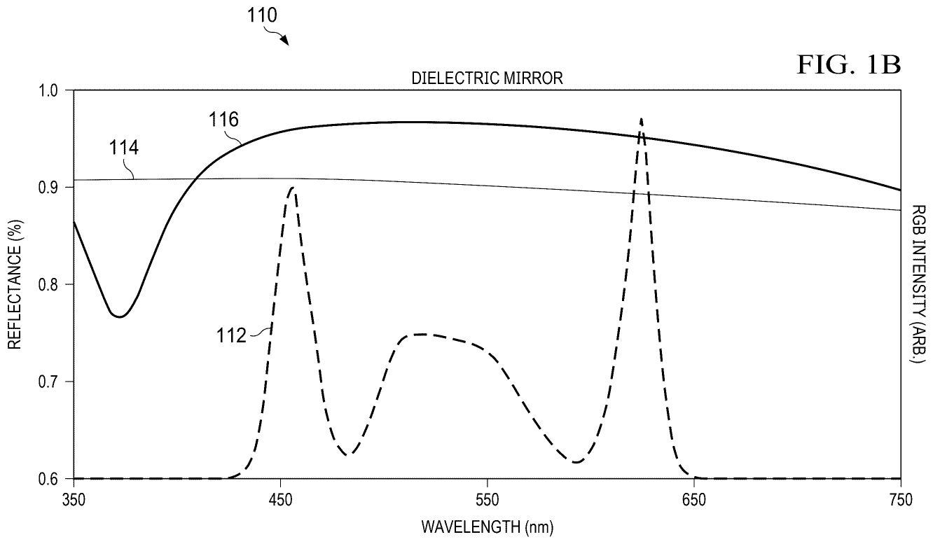

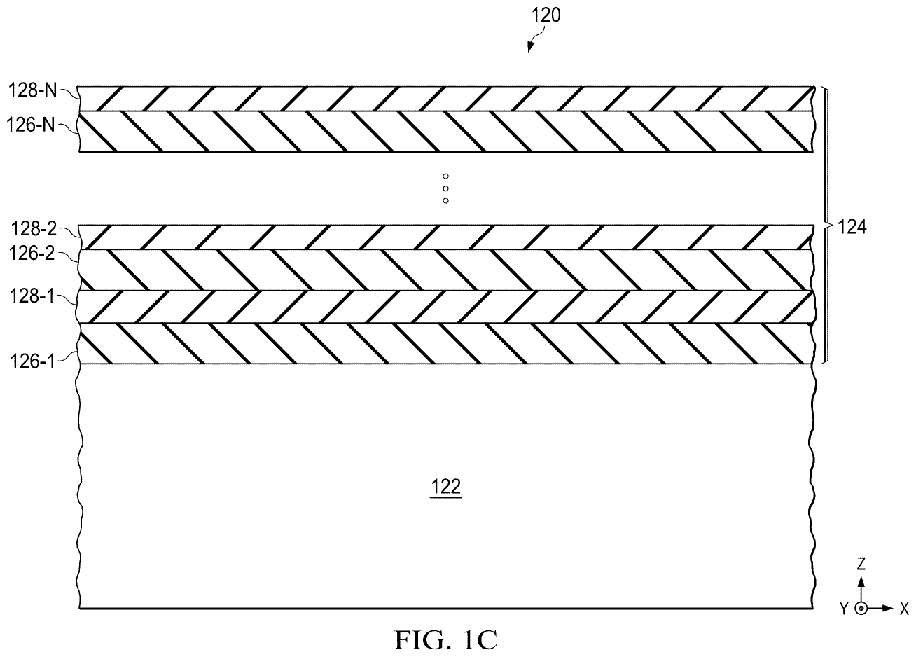

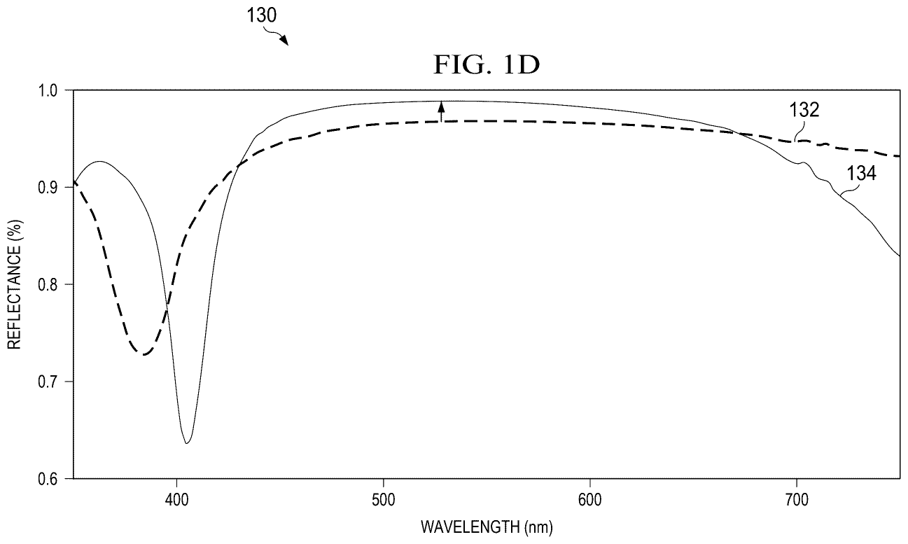

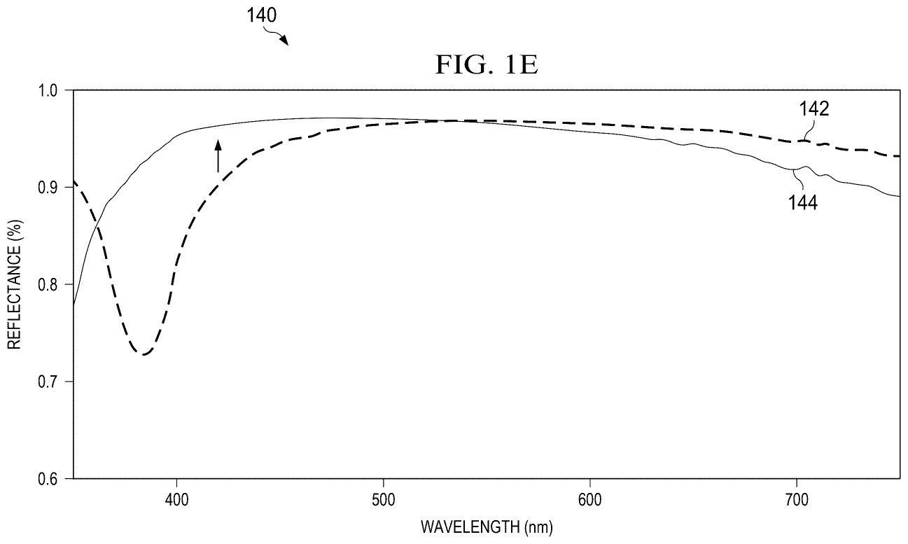

Referring now to FIG. 1A, a MEMS device 100 is shown including one or more layers of a MEMS structure 102 and a dielectric stack 104 formed over the one or more layers of the MEMS structure 102. In the example of FIG. 1A, the dielectric stack 104 includes a first dielectric layer 106 having an index of refraction n₁ and a second dielectric layer 108 having an index of refraction n₂, where n₂ is greater than n₁. As shown, the first dielectric layer 106 is on the one or more layers of the MEMS structure 102, and the second dielectric layer 108 is on the first dielectric layer 106.

In some examples, the first dielectric layer 106 is a silicon oxide layer, e.g., SiO₂, having an index of refraction n₁ equal to about 1.50, and the second dielectric layer 108 is a titanium oxide layer, e.g., TiO₂, having an index of refraction n₂ equal to about 2.50. Further, in some examples, the thickness (Z direction) of the first dielectric layer 106 is about 75 nanometers (nm) and the thickness (Z direction) of the second dielectric layer 108 is about 60 nm. In some examples, the first dielectric layer 106 has a minimum thickness (Z direction) of about 55nm and a maximum thickness (Z direction) of about 95 nm, and the second dielectric layer 108 has a minimum thickness (Z direction) of about 38 nm and a maximum thickness (Z direction) of about 78 nm. Thicknesses for the first dielectric layer 106 and the second dielectric layer 108 which are closer to these minimum values increase the reflectance of shorter wavelengths (e.g., around 400 nm) while thicknesses for the first dielectric layer 106 and the second dielectric layer 108 which are closer to these maximum values increase the reflectance of longer wavelengths (e.g., around 800 nm). The specific thicknesses of these films can be chosen to uniformly increase the reflectance across the visible light spectrum and for infrared light. The film thicknesses will increase to enhance the reflectance at longer wavelengths of infrared light. Other examples may include different thicknesses and refraction indices as needed/desired for given design goals such as increasing or decreasing the reflectance for other wavelengths. In additional examples, as will be further described below, the first dielectric layer 106 and the second dielectric layer 108 are formed on the one or more layers of the MEMS structure 102 via a thin film deposition process.

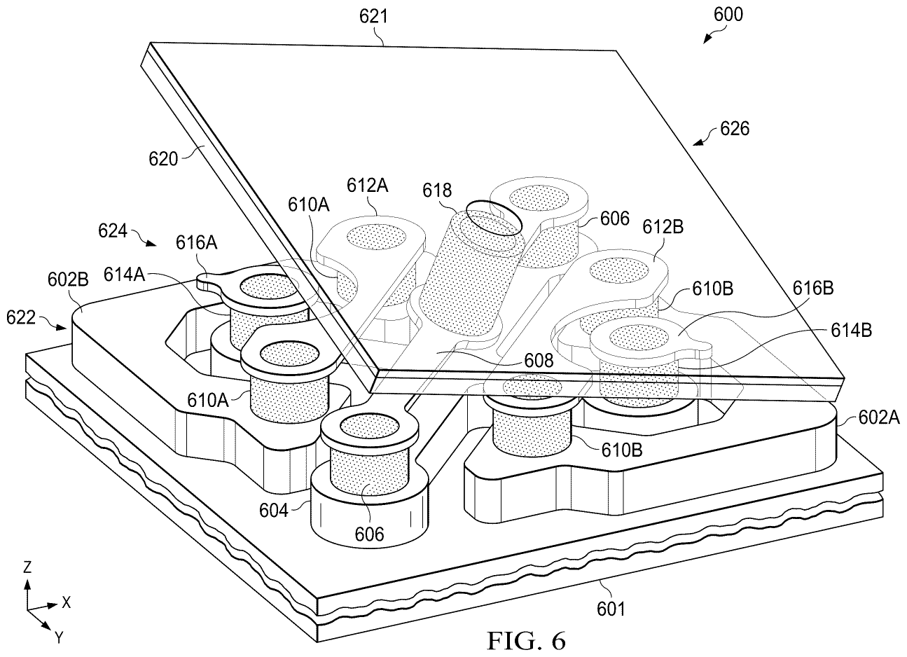

In some examples, the one or more layers of the MEMS structure 102 can represent a MEMS device, for example, as will be described below in the context of FIGS. 6-11B, or some other micromirror device. The MEMS structure 102 may be formed, at least in part, of aluminum in some examples. The particular material chosen for the MEMS structure 102 will affect the reflectance. Different sets of films with optimized indices of refraction and thicknesses may be selected to increase the reflectance for other types of materials used for the MEMS structure 102.

Advantageously, the dielectric stack 104 increases the reflectivity of the mirror on which it is formed. For example, by forming at least one pair of low and high (relative to one another) index of refraction films (e.g., the first dielectric layer 106 having an index of refraction lower than the index of refraction of the second dielectric layer 108) on a mirror layer (or other metal layer), reflectivity of the mirror layer is increased. The increase is due, at least in part, to interference effects. More particularly, as illustrated in FIG. 1A, incident light passes through the second dielectric layer 108 and a first portion of the incident light reflects (reflected light 1) at the boundary of the second dielectric layer 108 and the first dielectric layer 106, while a second portion of the incident light reflects (reflected light 2) at the boundary of the first dielectric layer 106 and the one or more layers of the MEMS structure 102. The reflected light 1 and the reflected light 2 constructively interfere with one another such that their peaks and troughs align resulting in a light beam with a larger amplitude and increased intensity. As such, the light reflected from the MEMS device 100 has an increased reflectance, achieved by the dielectric stack 104, as compared to a MEMS device without such a dielectric stack.

In other examples, more than one pair of alternating layers of dielectric materials with different indices of refraction can be used depending on the wavelength of the incident light. Thus, a one pair of first and second dielectric layers having different indices of refraction can be formed on another pair of first and second dielectric layers having different indices of refraction, and so on.

FIG. 1B depicts a graphical example 110 of increased reflectance provided by the dielectric stack 104. As shown, in a non-limiting use case, for incident light having varying illumination 112 between wavelengths of 350 nm and 750 nm, a curve 114 represents reflectance when a dielectric stack according to one or more examples is not used in the micromirror device, while a curve 116 represents increased reflectance, relative to curve 114, when a dielectric stack according to one or more examples is used. The reflectance spectra can be adjusted by changing the film index of refraction or thickness of the dielectric stack 104, or by adding additional alternating layers of high and low index of refraction dielectrics. In one example, curve 116 is the reflectance for a dielectric film stack of the MEMS device 100 of FIG. 1A, where the second dielectric layer 108 is 58 nm film of TiO₂ and the first dielectric layer 106 is a 750 nm film of SiO₂. This provides approximately a 5-7% increase in reflectance for wavelengths of 400 to 650 nm. To optimize the dielectric film stack of the MEMS device 100 of FIG. 1A for longer wavelengths, the thicknesses of the first dielectric layer 106 and the second dielectric layer 108 may be increased. For shorter wavelengths, the thicknesses of the first dielectric layer 106 and the second dielectric layer 108 may be decreased. When large changes are made to the index of refraction of the thickness of the dielectric stack, the shape of the reflectance curve is affected.

By way of further example, FIG. 1C illustrates a MEMS device 120 with a MEMS substrate 122 having a dielectric stack 124 with two or more sets of alternating layers of high and low index of refraction dielectrics. As shown, the dielectric stack 124 includes a first set of alternating dielectric layers 126-1 and 128-1 (e.g., the dielectric layer 126-1 having an index of refraction lower than the index of refraction of the dielectric layer 128-1), a second set of alternating dielectric layers 126-2 and 128-2 (e.g., the dielectric layer 126-2 having an index of refraction lower than the index of refraction of the dielectric layer 128-2), and an Nth set of alternating dielectric layers 126-N and 128-N (e.g., the dielectric layer 126-N having an index of refraction lower than the index of refraction of the dielectric layer 128-N). Depending on the wavelength of the light being reflected and/or the desired reflectance spectra, in some examples, each set of alternating layers can be the same or similar in materials, thicknesses, and refraction indices; while in other examples, some of the sets of alternating layers may be different in one or more of materials, thicknesses, and refraction indices than others of the sets of alternating layers. In some examples, the dielectric stack 124 includes four layers - the first set of alternating layers 126-1 and 128-2 and the second set of alternating layers 126-2 and 128-2. In one example, dielectric layers 126-1 and 126-2 are 75 nm SiO₂ films, and the dielectric layers 128-1 and 128-2 are 58 nm films of TiO₂. This increases the reflectance at a wavelength of 500 nm from 97% to 99%. FIG. 1D depicts a graphical example 130 of increased reflectance provided by the dielectric stack 124 including four layers, as compared with a dielectric stack 104 including two layers. As shown, in a non-limiting use case, for incident light having varying illumination (e.g., 112 as shown in FIG. 1B), curve 132 represents the reflectance when the dielectric stack 104 including two layers is used, while curve 134 represents the reflectance when the dielectric stack 124 with four layers is used. A disadvantage of use of additional films in the dielectric stack 124 is that the bandwidth of reflectivity enhancement can be reduced. In this example, the reflectance at a wavelength of 700 nm is reduced from 95% to 93%. Another disadvantages of the use of additional films in the dielectric stack 124 is the additional mass used in the micromirror, as well as additional processing steps that can add cost and complexity to the process flow.

FIG. 1E depicts a graphical example 140 of reflectance provided by the dielectric stack 104 having two dielectric layers, with differing thicknesses of the first dielectric layer 106 and the second dielectric layer 108. For incidence light having varying illumination (e.g., 112 as shown in FIG. 1B), curve 142 represents the reflectance for a configuration where the first dielectric layer 106 is a SiO₂ film with a thickness of 75 nm and the second dielectric layer 108 is a TiO₂ film with a thickness of 58 nm, and curve 144 represents the reflectance for a configuration where the first dielectric layer 106 is a SiO₂ film with a thickness of 65 nm and the second dielectric layer 108 is a TiO₂ film with a thickness of 48 nm. As illustrated, the thicknesses of the layers in the dielectric stack 104 can be adjusted to optimize the reflectance for specific wavelengths. In this example, reducing the film thicknesses provides an increase in reflectance at 420 nm from 90% to 96%.

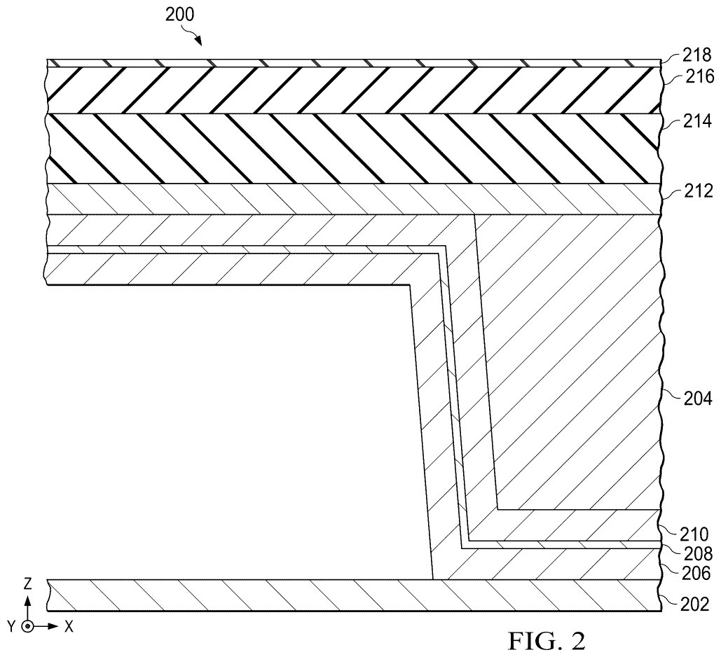

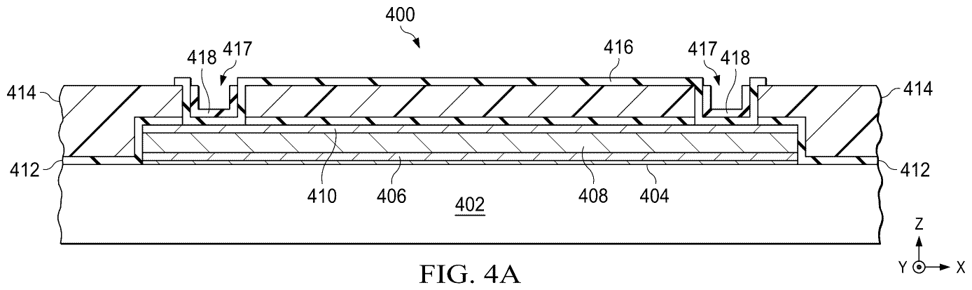

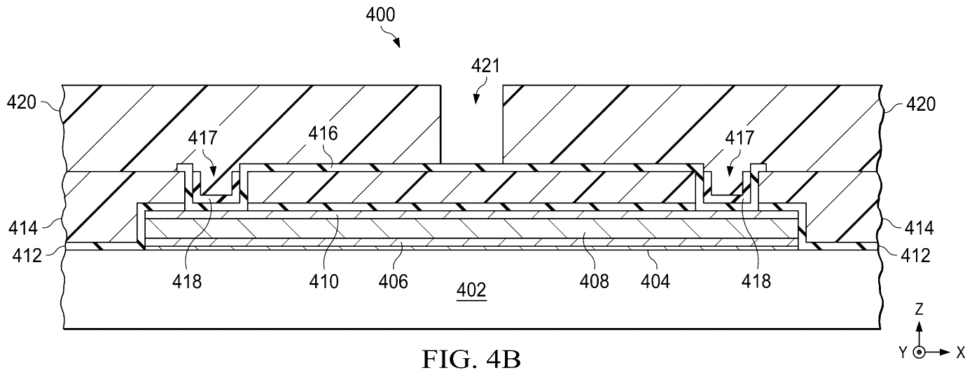

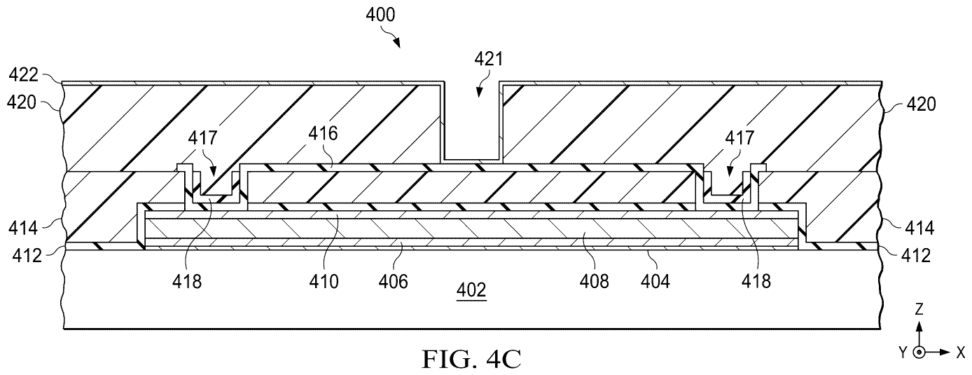

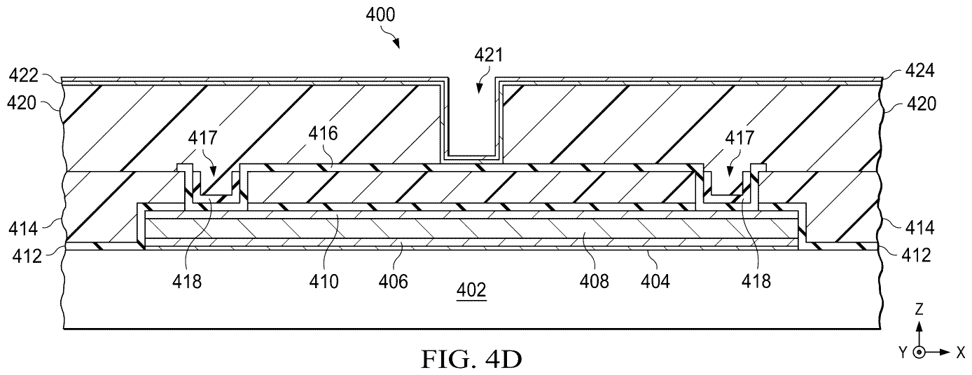

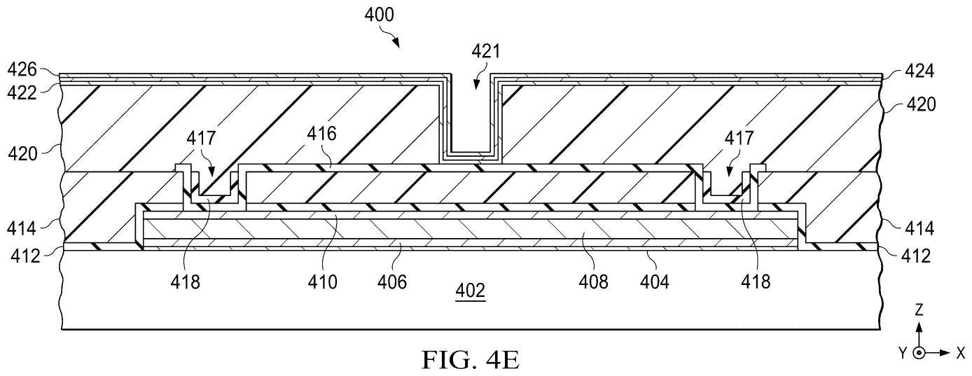

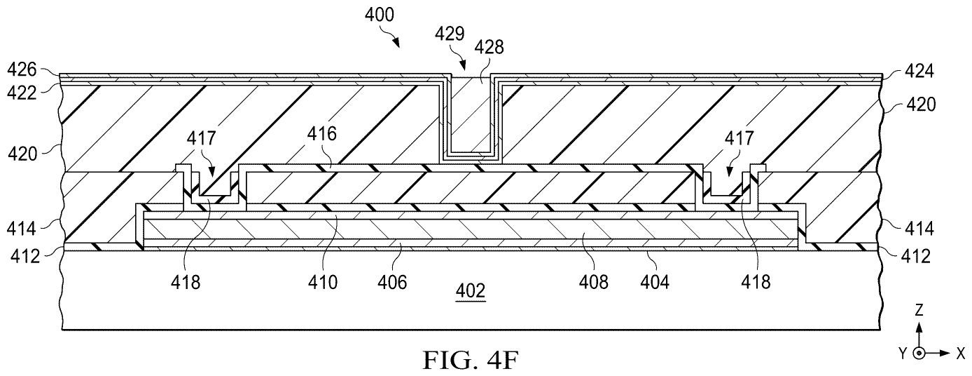

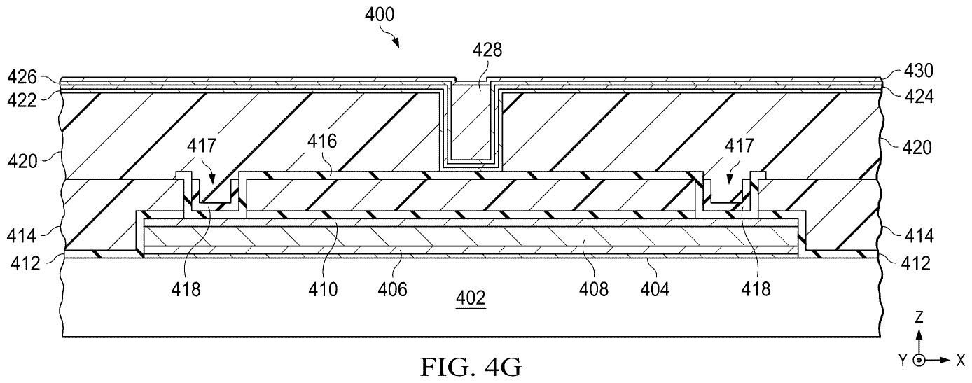

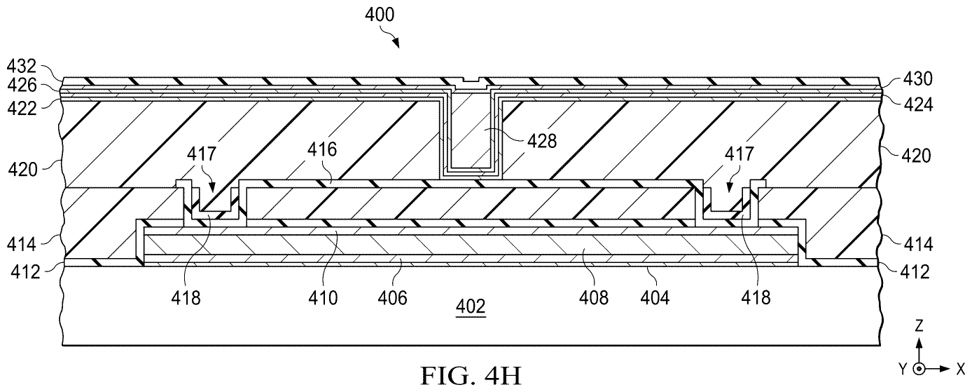

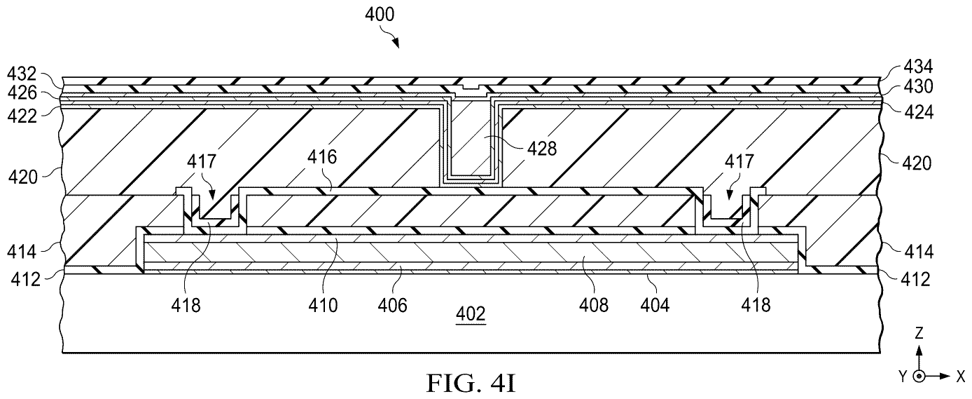

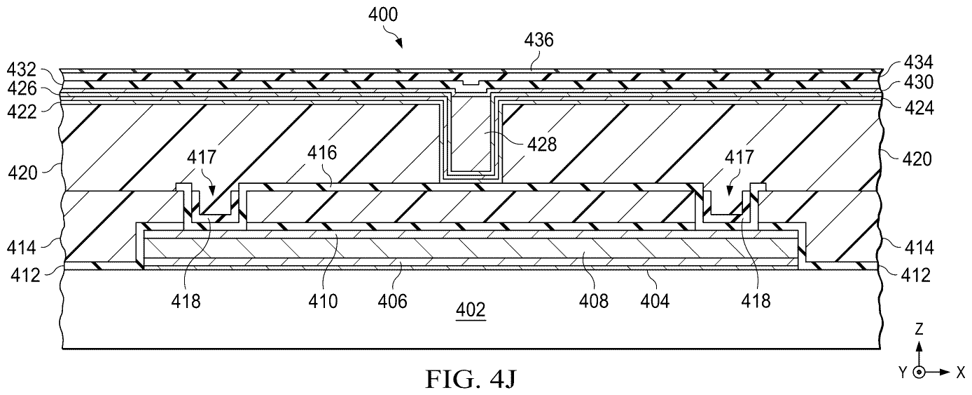

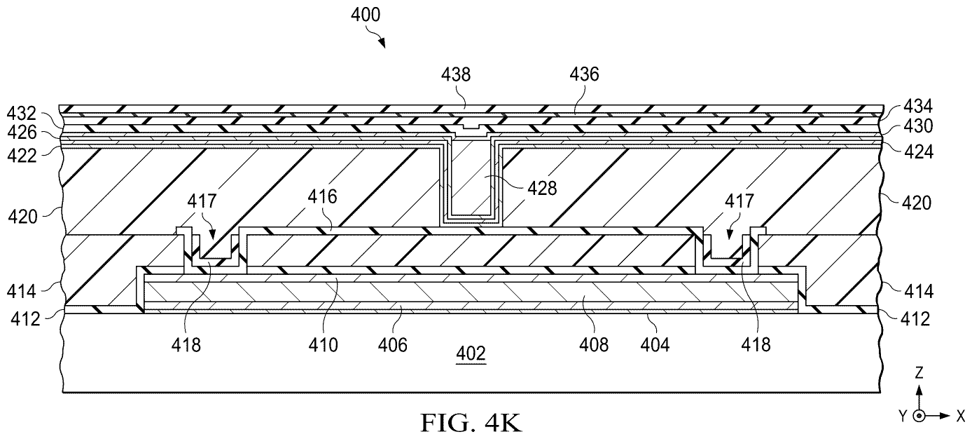

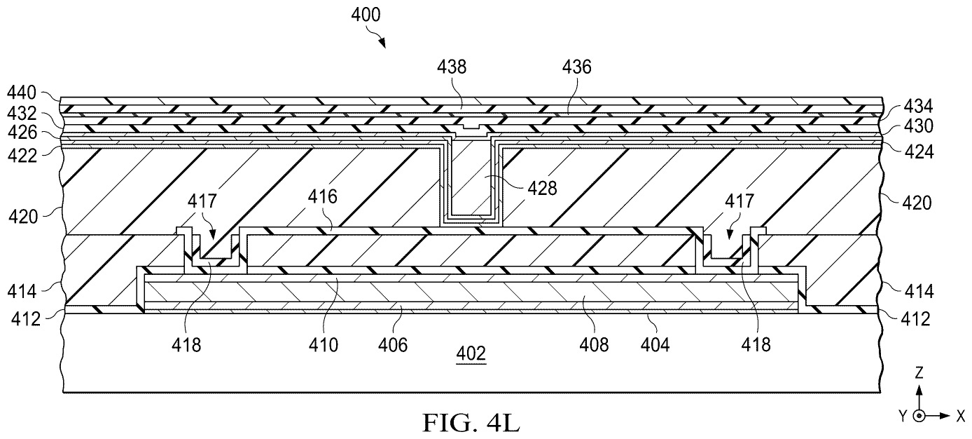

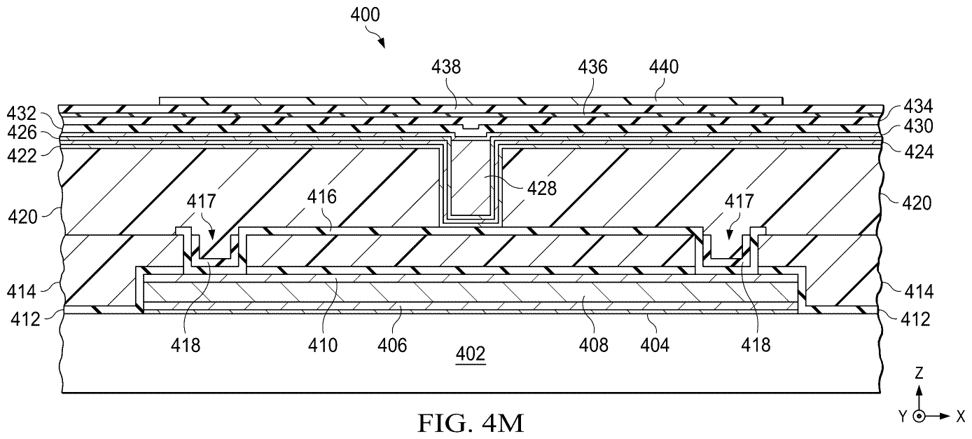

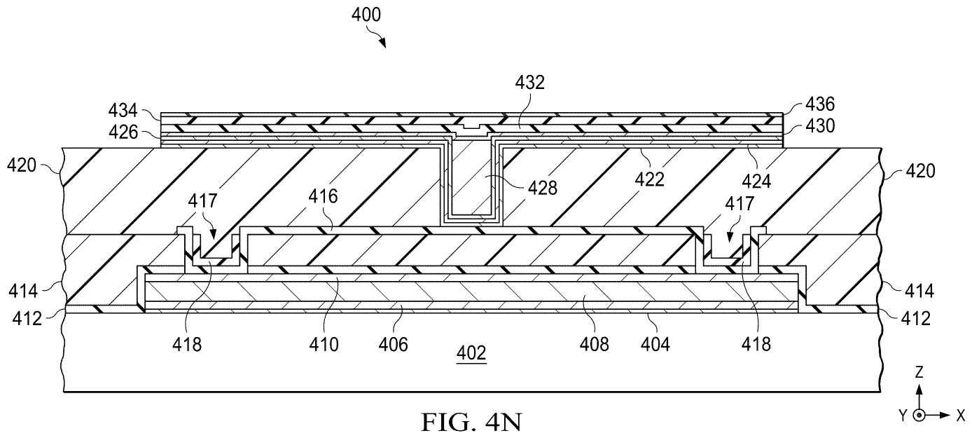

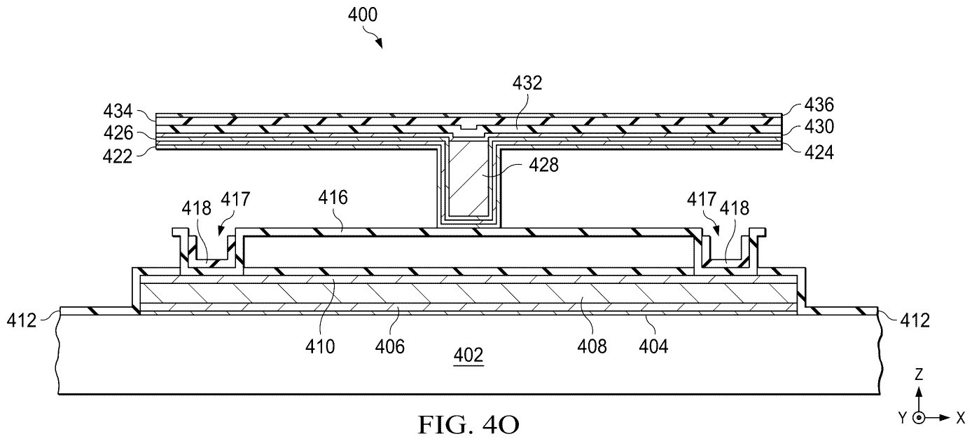

FIG. 2 is a cross-sectional view of a portion of a micromirror device (e.g., MEMS device) 200 in accordance with one or more other examples. More particularly, in addition to a dielectric stack formed the same or similar to dielectric stack 104 in FIG. 1A, micromirror device 200 also includes a dielectric layer (e.g., providing protective functionality, and thus sometimes referred to as a protective layer) and an alloy layer (e.g., providing stress control functionality, and thus sometimes referred to as a stress control layer), as will be further described below. In some examples, micromirror device 200 can be otherwise configured the same or similar to MEMS device 100 or any of the MEMS devices which will be described in further detail below with respect to FIGS. 4A-11B, as well as other configurations.

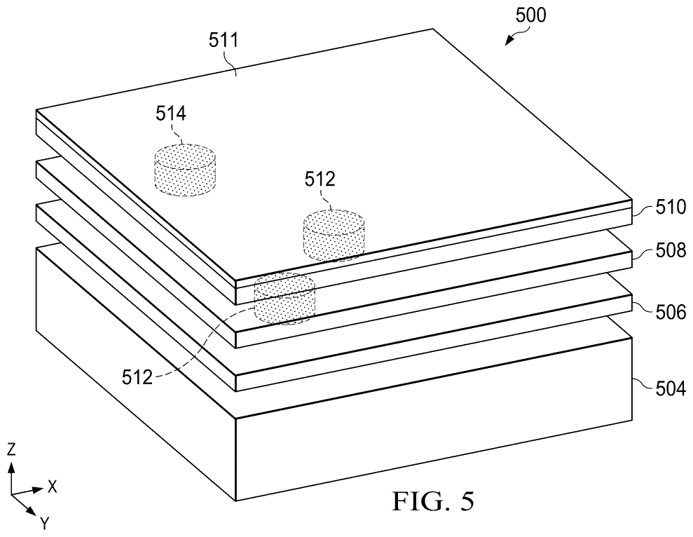

As shown, micromirror device 200 includes a hinge 202, a fill layer 204, a first metal layer 206, an alloy layer 208 (sometimes referred to as stress control layer 208), a second metal layer 210, a third metal layer 212, a first dielectric layer 214, a second dielectric layer 216, and a third dielectric layer 218 (sometimes referred to as protective layer 218). The hinge 202 may be considered part of a mechanical layer (e.g., similar to mechanical layer 508 of MEMS device 500 in FIG. 5, described below), while the entire mirror (e.g., including the first metal layer 206, the alloy layer 208, the second metal layer 210, the third metal layer 212, the first dielectric layer 214, the second dielectric layer 216, and the third dielectric layer 218) is moved by rotation of the hinge 202 and thus may be considered part of a movable elements layer (e.g., similar to movable element(s) layer 510 of MEMS device 500 in FIG. 5, described below). In some examples, the hinge 202 may be formed of a metal material such as a titanium and aluminum alloy. In other examples, the hinge 202 may be formed of aluminum. The fill layer 204 can be formed of an organic gap filling polymer, such as Brewer Science Inc.'s GF26 series gap fill polymer. It should be noted that the use of a “filled” mirror via is optional. For the fill layer 204, the mirror metal is deposited using at least two metal deposition processes (e.g., top layer 212 and bottom mirror metal layer 206). If the mirror via is not filled, the additional top mirror layer 212 is not needed. If the mirror via is not filled, however, the mirror brightness and contrast would be lower. A base layer and electrode layer for micromirror device 200 are not expressly shown. The first metal layer 206 may be formed of a metal material such as aluminum, titanium, a titanium aluminum alloy, titanium nitride, or aluminum oxide. The second metal layer 210 may be formed of a metal material such as aluminum, titanium, a titanium aluminum alloy, titanium nitride, or aluminum oxide. The third metal layer 212 may be formed of a metal material such as aluminum, titanium, a titanium aluminum alloy, titanium nitride, or aluminum oxide. In some examples, each of the first metal layer 206, the second metal layer 210 and the third metal layer 212 are formed of the same material. In other examples, the first metal layer 206, the second metal layer 210 and the third metal layer 212 may be formed of different materials.

In some examples, the first metal layer 206, the second metal layer 210, and the third metal layer 212 are part of a mirror layer, while the first dielectric layer 214 and the second dielectric layer 216 are part of a dielectric stack (e.g., similar to dielectric stack 104 of MEMS device 100 in FIG. 1A) formed on the mirror layer to provide increased reflectance as described above. In some examples, the first dielectric layer 214 and the second dielectric layer 216 can be SiO₂ and TiO₂, respectively. In other examples, the first dielectric layer 214 may be a silicon nitride (SiN) film formed with a process chosen to achieve a lower index of refraction, and the second dielectric layer 216 may be a SiN film formed with a process chosen to achieve a higher index of refraction. In some examples, the thickness (Z direction) the first dielectric layer 214 is about 60 to 100 nm and the thickness (Z direction) of the second dielectric layer 216 is about 50 to 70 nm for film stacks optimized for the visible spectrum from wavelengths of 450 to 700 nm. Other dielectrics of other thicknesses with varying indices of refraction can be used in other examples.

Additionally, the third dielectric layer 218 is formed on the second dielectric layer 216 to provide protection to the dielectric stack, e.g., first dielectric layer 214 and the second dielectric layer 216. In some examples, the protection may include preventing or otherwise reducing moisture absorption by the micromirror device 200, and preventing or otherwise reducing micromirror stress and shape changes, as well as other protections. In some examples, the third dielectric layer 218 is aluminum oxide (e.g., Al₂O₃). The aluminum oxide, in some examples, prevents reactivity of the second dielectric layer 216. In other examples, the third dielectric layer 218 is formed of SiN. In some examples, the third dielectric layer 218 has a thickness (Z direction) of about 4.5 nm. Other dielectrics of other thicknesses can be used in other examples.

Still further, in some examples, the alloy layer 208 formed between the first metal layer 206 and the second metal layer 210 provides the ability to target specific micromirror shape and uniformity characteristics. In some examples, the alloy layer 208 includes an alloy such as titanium aluminide (e.g., TiAl₃) having a thickness (Z direction) of about 10 nm. It should be noted that the alloy layer 208 could be located in a different position than shown. In some examples, the alloy layer 208 is below the first metal layer 206, or is between the second metal layer 210 and the third metal layer 212. In some examples, the first metal layer 206, the second metal layer 210, and the third metal layer 212 include aluminum of different thicknesses (Z direction), e.g., the first metal layer 206 being about 50 nm, the second metal layer 210 being about 40 nm, and the third metal layer 212 being about 30 nm. Other metals of other thicknesses can be used in other examples. If the alloy layer 208 is used, the first metal layer 206 and the second metal layer 210 must be deposited separately, though they may be the same material. Similarly, use of a “filled” mirror via requires the third metal layer 212 to encapsulate the fill layer 204.

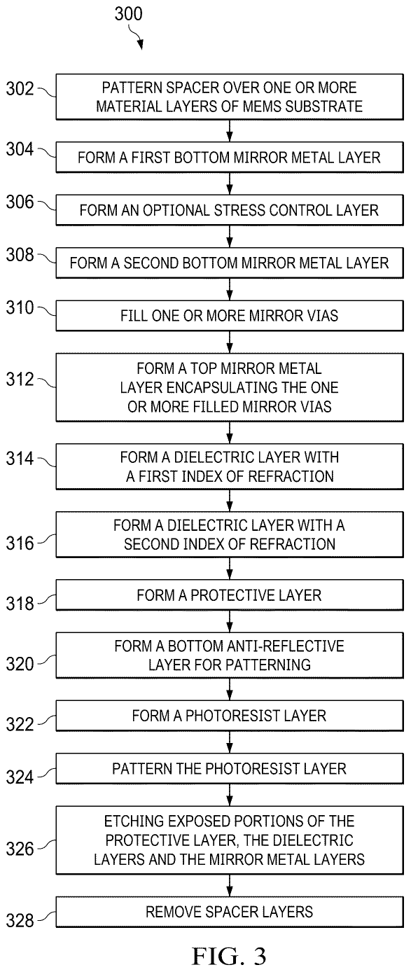

FIG. 3 is a flow diagram of a method 300 for forming a MEMS device with a dielectric stack in accordance with various examples herein. The steps of the method 300 may be performed in any suitable order. The method 300 begins in step 302 with patterning a spacer layer over one or more material layers (e.g., metal layers) of electrode control circuitry for the MEMS device. The electrode control circuitry may include multiple metal routing, silicon and transitory levels. In some examples, the electrode control circuitry comprises one or more CMOS memory cells. The spacer layer may comprise a spin-on carbon (SOC) layer or a relatively thick photoresist layer. Step 302 may include depositing an organic polymer layer on the one or more material layers of the electrode control circuitry and thermally curing the organic polymer layer. This deposition and thermal curing may be repeated as desired to increase the total thickness of the spacer layer. Step 302 may further include depositing a hard mask on the organic polymer layer, depositing a photoresist layer on the hard mask, patterning the photoresist layer to expose at least a portion of the hard mask, etching the exposed portion of the hard mask to expose at least a portion of the organic polymer layer, and etching the exposed portion of the organic polymer layer to expose at least a portion of the one or more material layers of the electrode control circuitry. In other examples, step 302 may include depositing a photoresist layer and patterning the photoresist layer without use of a hard mask.

The method 300 continues with step 304, forming a first bottom mirror metal layer for a mirror structure of a MEMS device. The first bottom mirror metal layer forms the sidewalls of the mirror via where the sacrificial layer (e.g., SoC or photoresist) has been removed, in addition to forming the mirror. The first bottom mirror metal layer is formed on the sacrificial layer and on the MEMS structure and hinge. In step 306, an optional alloy layer (e.g., a stress control layer) is formed on the first bottom mirror metal layer. The alloy layer includes an optional deposition of one or more layers that control the stress and shape of the mirror structure of the MEMS device. Following step 306, an optional second bottom mirror metal layer for the mirror structure of the MEMS device is formed on the optional alloy layer in step 308. In an optional step 310, a fill layer is formed (e.g., one or more filled portions for one or more filled mirror vias (FMVs)). A top mirror metal layer for the mirror structure of the MEMS device is then formed in step 312 over the second bottom mirror metal layer and the FMVs. The top mirror metal layer encapsulates the one or more FMVs.

A first dielectric layer with a first index of refraction is formed in step 314 over the top mirror metal layer, followed by formation of a second dielectric layer with a second index of refraction in step 316 over the first dielectric layer. The first index of refraction may be lower than the second index of refraction. The first dielectric layer may be silicon dioxide (SiO₂), while the second dielectric layer may be titanium oxide (TiO₂). Steps 314 and 316 result in formation of a dielectric bilayer for the mirror structure for the MEMS device. In some examples, steps 314 and 316 are repeated to further increase reflectance or tailor the reflectance of the mirror structure for the MEMS device to a specific wavelength. In step 318, a third dielectric layer (e.g., a protective layer) is formed over the second dielectric layer. The third dielectric layer may be formed of aluminum oxide (Al₂O₃).

In step 320, a bottom anti-reflective layer is formed. The bottom anti-reflective layer, which may be a bottom anti-reflective coating (BARC) layer, facilitates patterning of the mirror structure for the MEMS device. The BARC layer is a spin-coated material applied under or on top of a photoresist before being exposed. This helps to improve the critical dimension (e.g., mirror gaps) uniformity and consistency by reducing the reflectance of the substrate. In this case, the substrate is a relatively bright mirror layer that would reflect light. This reflected light interferes with the incoming light and changes how the photoresist is exposed. The BARC layer is formed of BARC materials designed to absorb light and planarize the surface that is being patterned. Photoresist thickness variations are another source of critical dimension variation.

Furthermore, the BARC layer may provide a hard mask. A photoresist layer is then formed in step 322, followed by patterning of the photoresist layer to expose at least a portion of the mirror structure for the MEMS device (e.g., metal mirror layers and dielectric layers) in step 324. In step 326, exposed portions of the third dielectric layer, the first and second dielectric layers, the metal mirror layers and the optional alloy layer are etched. Step 326 may utilize multi-step mirror dielectric and metal etch processing. For example, the third dielectric layer formed of Al₂O₃ may be etched using a boron trichloride (BCl₃) and chlorine gas (Cl₂) chemistry. The second dielectric layer formed of TiO₂ and the first dielectric layer formed of SiO₂ may be etched using a trifluoromethane (CHF₃) and chlorine gas (Cl₂) chemistry. The first dielectric layer formed of SiO₂ may be etched using a CHF₃/Cl₂ chemistry. The top and bottom mirror metal layers formed of Al may be etched using a BCl₃ and Cl₂ chemistry. The spacer layer (formed in step 302) is then removed in step 328. The spacer layer may be removed using an undercut or MEMS release process, such as an isotropic plasma ash process that etches organic films and does not etch the metal and oxide films that provide the micromirrors.

FIGS. 4A-4O show respective cross-sectional views illustrating fabrication of a dielectric stack for a mirror structure of a MEMS device 400. The fabrication process illustrated in FIGS. 4A-4O represents an example implementation of the method 300.

FIG. 4A shows a portion of a structure of the MEMS device 400 in accordance with an example herein, prior to step 302 of the method 300. The structure includes a MEMS substrate 402, a set of metal layers 404, 406, 408 and 410, an anti-reflective coating (ARC) layer 412, a first spacer layer 414, a hinge layer 416, vias 417, and a hinge oxide layer 418. Although not shown, complementary metal oxide semiconductor (CMOS) memory cells may be formed under the MEMS substrate 402 with several metal and dielectric layers and a final bottom substrate formed of silicon or another suitable semiconductor material.

In some examples, hinge oxide layer 418 is relatively thick to provide better mechanical stability. For example, hinge oxide layer 418 may be created by depositing an oxide layer on the hinge layer 416 and then using an etch back process leaving the oxide layer at least partially on the sidewalls, as shown in FIG. 4A.

The metal layer 404 may be formed of a first material, such as titanium (Ti). The metal layers 406 and 410 may be formed of a second material, such as titanium nitride (TiN). The metal layer 408 may be formed of a third material, such as aluminum (Al). In some examples, the metal layer 404 formed of titanium provides an adhesion layer for aluminum (e.g., the material of the metal layer 408), while the metal layers 406 and 410 formed of titanium nitride provides a capping layer for aluminum and allow for the formation of low resistance via connections. The ARC layer 412, which may be referred to as an anti-reflective coating oxide (ARCox) layer 412, provides an ARC for components of a final MEMS device following removal of first spacer layer 414. The ARC layer 412 may include a deposited silicon dioxide (SiO₂) layer that is part of an anti-reflective multilayer thin film system that reduces reflectance from the set of metal layers 404, 406, 408 and 410.

The first spacer layer 414 may be deposited, patterned and etched to create the shape and structure of the hinge layer 416 as shown in FIG. 4A. The first spacer layer 414 may be formed of spin-on carbon (SOC), which is a type of organic spin-coated polymer. Other organic spin-coated polymers or a relatively thick layer of photoresist may be used in some examples. In one example, the organic polymer may be a spin-on dielectric material. In another example, the organic polymer may be a spin-on filling material for topography planarization. In another example, the organic polymer may be an anti-reflective coating (ARC) for minimizing a standing wave and improving critical dimension uniformity. An organic polymer is a macromolecule composed of many repeating monomer units that contain carbon in the backbone.

The hinge layer 416 is then formed, followed by the hinge oxide layer 418. The hinge layer 416 may be formed of a metal or an alloy, such as a titanium-aluminum (TiAl₃) alloy. The hinge layer 416 may be a deposited film formed using any suitable technique used to make thin metal films, such as evaporation, physical vapor deposition (PVD), atomic layer deposition (ALD), etc. The hinge oxide layer 418 is formed of an oxide material. The hinge oxide layer 418 may be formed by depositing an oxide on the surface of the hinge layer 416, followed by an etch-back process such that the hinge oxide layer 418 remains only on sidewalls of the hinge layer 416 as illustrated. The relatively thick hinge oxide layer 418 provides improved mechanical stability.

FIG. 4B shows the structure of FIG. 4A following deposition and patterning of a second spacer layer 420 (e.g., step 302 in method 300). The second spacer layer 420 may be an organic polymer layer, such as SOC, that is deposited on the hinge layer 416. The organic polymer layer may be thermally cured. There may be multiple steps of depositing and thermally curing the organic polymer layer to reach a desired thickness for the second spacer layer 420. A hard mask (not shown) is then deposited on the second spacer layer 420, followed by deposition and patterning of a photoresist (not shown) over the hard mask. The hard mask is then etched (e.g., using a fluorine-based etch) to expose a portion of the second spacer layer 420, followed by etching (e.g., using an oxygen-based etch) of the second spacer layer 420 in region 421 which exposes the hinge layer 416. The remainder of the hard mask is then removed. In other examples, the spacer layer is photoresist that is exposed.

FIG. 4C shows the structure of FIG. 4B, following deposition of a first bottom mirror metal layer 422 for a mirror structure for the MEMS device 400 (e.g., step 304 in method 300). The first bottom mirror metal layer 422 may be formed by depositing a layer of aluminum (Al) through physical vapor deposition (PVD).

FIG. 4D shows the structure of FIG. 4C following deposition of an optional alloy layer 424 over the first bottom mirror metal layer 422 (e.g., step 306 in method 300). The alloy layer 424 may be formed by depositing a layer of titanium aluminum alloy (TiAl₃) through PVD.

FIG. 4E shows the structure of FIG. 4D following deposition of second bottom mirror metal layer 426 over the optional alloy layer 424 (e.g., step 308 in method 300). The second bottom mirror metal layer 426 may be formed by depositing a layer of aluminum (Al) film through PVD.

FIG. 4F shows the structure of FIG. 4E following formation of a filling 428 in a filled mirror via (FMV) 429 (e.g., step 310 in method 300). The FMV 429 is created by applying an organic gap fill layer through spin coating, followed by pattern and etch processes to remove the gap fill material from the top of the mirror and leaving it in the mirror via.

FIG. 4G shows the structure of FIG. 4F following formation of top mirror metal layer 430 (e.g., step 312 in method 300). The top mirror metal layer 430 may be formed by depositing a layer of aluminum (Al) film through PVD.

FIG. 4H shows the structure of FIG. 4G following formation of a first dielectric layer 432 (e.g., step 314 in method 300). The first dielectric layer 432 may be formed of silicon dioxide (SiO₂). The first dielectric layer 432 may be formed through chemical vapor deposition (CVD), PVD, or by atomic layer deposition (ALD).

FIG. 4I shows the structure of FIG. 4H following formation of a second dielectric layer 434 (e.g., step 316 in method 300). The second dielectric layer 434 may be formed of titanium oxide (TiO₂). The second dielectric layer 434 may be formed through CVD, PVD, or by ALD.

The first dielectric layer 432 and the second dielectric layer 434 provide a dielectric bilayer (e.g., similar to the dielectric stack 104 described above). In some examples, steps 314 and 316 are repeated to form multiple dielectric bilayers to further increase reflectance or tailor the overall reflectance to a specific wavelength.

FIG. 4J shows the structure of FIG. 4I following formation of a third dielectric layer 436 (e.g., step 318 in method 300). The third dielectric layer 436 may be formed of aluminum oxide (Al₂O₃). The third dielectric layer 436 may be formed through ALD.

FIG. 4K shows the structure of FIG. 4J following formation of BARC layer 438 (e.g., step 320 in method 300). The BARC layer 438 is utilized for patterning, and provides a hard mask for subsequent patterning steps.

FIG. 4L shows the structure of FIG. 4J following deposition of photoresist layer 440 (e.g., step 322 in method 300).

FIG. 4M shows the structure of FIG. 4L following patterning of the photoresist layer 440 to expose at least a portion of the underlying mirror and dielectric layers (e.g., step 324 in method 300).

FIG. 4N shows the structure of FIG. 4M following etching of exposed portions of the BARC layer 438, the third dielectric layer 436, the second dielectric layer 434, the first dielectric layer 432, the top mirror metal layer 430, the optional alloy layer 424, the second bottom mirror metal layer 426 and the first bottom mirror metal layer 422 (e.g., step 326 in method 300), followed by removal of the photoresist layer 440 and the BARC layer 438. These etchings may be performed in multiple steps, as part of an integrated in-situ process where the photoresist layer 440 is used as a mask structure and a multi-step etch using two or more etch chemistries is utilized. For example, the third dielectric layer 436 (e.g., formed of Al₂O₃) may be etched using a boron trichloride and chlorine gas (BCl₃/Cl₂) chemistry. The second dielectric layer 434 (e.g., formed of TiO₂) may be etched using a trifluoromethane and chlorine gas (CHF₃/Cl₂) chemistry. The first dielectric layer 432 (e.g., formed of SiO₂) may be etched using a CHF₃/Cl₂ chemistry. The top mirror metal layer 430, the optional alloy layer 424, the second bottom mirror metal layer 426 and the first bottom mirror metal layer 422 may be etched using a BCl₃/Cl₂ chemistry.

FIG. 4O shows the structure of FIG. 4N following removal of the second spacer layer 420 and the first spacer layer 414 (e.g., step 328 in method 300). The first spacer layer 414 and the second spacer layer 420 may be removed through an isotropic plasma etch process which releases the mirrors. In some examples, the isotropic plasma etch uses an oxygen-based plasma with a high etch rate of organic layers and low etch rate of metal and oxide layers.

Before describing further details of the dielectric stack and other structural features of the above examples, some example configurations of MEMS devices and micromirror devices with which one or more examples of the present disclosure can be implemented will first be described.

In some example configurations, each MEMS device can be a micromirror device configured as a pixel of a display. In different example configurations, such MEMS devices are organized into an array of pixels for a spatial light modulator (SLM), such as a digital micromirror device (DMD), or a phase light modulator (PLM). As will be further described below, an SLM is configured to spatially modulate one or more of an amplitude, phase, and polarization of a light wave to achieve specific optical patterns and desired image characteristics. A PLM is configured to specifically focus on phase modulation, particularly in optical applications benefitting from fast switching speeds, e.g., holographic imaging, light beam steering, etc. The PLM is also useful for high dynamic range (HDR) when combined with an SLM, and augmented reality (AR). While some figures are directed to a single MEMS device or pixel, the related benefits (e.g., improved brightness, efficiency, contrast, protection, stress control, etc.) are applicable to a single pixel as well as devices with an array of pixels (e.g., a DMD, PLM, SLM, etc.).

Examples of the present disclosure provide for the formation of a dielectric stack on a corresponding mirror of a MEMS device, e.g., a micromirror device. By way of example, such a dielectric stack can be formed on mirror 620, mirror 720, the mirror 820, the mirror plate 910, and the mirror plate 1010, respectively, of the MEMS devices of FIGS. 6-10, to realize certain technical advantages described herein. Furthermore, a dielectric layer (e.g., a protective layer) and/or an alloy layer (e.g., a stress control layer) may be formed in/on such MEMS devices to realize certain other technical advantages described herein.

FIG. 5 is a three-dimensional view of a MEMS device 500 in accordance with one or more examples. The MEMS device 500 includes a base 504, an electrode layer 506, a mechanical layer 508, a movable element(s) layer 510, via(s) 512, and via(s) 514. In some examples, the base 504 includes memory cells and/or other circuitry (not shown) to control different states of the MEMS device 500 responsive to received data. In some examples, the electrode layer 506 includes electrodes coupled to the base 504. In some examples, via(s) 512 may include electrode vias, spring tip vias, and/or hinge vias. In some examples, the mechanical layer 508 includes one or more hinges, raised electrodes, spring tips, and/or other components. In some examples, via(s) 514 may include a mirror via. The via(s) 514 couple the hinge layer and the mirror layer. In some examples, the movable element(s) layer 510 includes a mirror. The mirror may include a dielectric stack 511. The dielectric stack 511, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 511 may include two or more sets of alternating layers of high and low index of refraction dielectrics, similar to the dielectric stack 124 shown in FIG. 1C.

The MEMS substrate 402 of MEMS device 400 of FIGS. 4A-4O may be considered part of the base 504 of MEMS device 500. The set of metal layers 404, 406, 408 and 410 of MEMS device 400 may be considered part of the electrode layer 506 of MEMS device 500. The hinge layer 416 of MEMS device 400 may be considered part of the mechanical layer 508 of MEMS device 500. The hinge oxide layer 418 of MEMS device 400 may be considered part of the via(s) 512 of MEMS device 500. The mirror structure including first bottom mirror metal layer 422, the optional alloy layer 424, the second bottom mirror metal layer 426, the top mirror metal layer 430, the first dielectric layer 432, the second dielectric layer 434 and the third dielectric layer 436 of MEMS device 400 may be considered part of the movable element(s) layer 510 of MEMS device 500. The vias 417 of MEMS device 400 are examples of vias coupling the mechanical layer to the electrode layer, similar to the via(s) 512 of MEMS device 500. The FMV 429 of MEMS device 400 is an example of a via coupling the mechanical layer to the movable elements layer, similar to the via(s) 514 of MEMS device 500.

In some examples, the via(s) 512 couple the mechanical layer 508 to the electrode layer 506. Additionally, or alternatively, the via(s) 514 may couple the mechanical layer 508 to the movable element(s) layer 510. In some examples, the MEMS device 500 may include filled vias, unfilled vias, or a combination thereof.

In an example SLM, the movable element(s) layer 510 of the MEMS device 500 tilts between two or more positions based on received data and operations of the base 504 and the mechanical layer 508 responsive to the received data. In an example PLM, the movable element(s) layer 510 of the MEMS device 500 moves up and down between two or more positions based on received data and operations of the base 504 and the mechanical layer 508 responsive to the received data. Without limitation, the MEMS device 500 may be used to form a pixel of a SLM or a PLM of a display system. Example pixel sizes that may benefit from the MEMS device 500 may range from about 16-micrometer (μm) pixels down to 2.7-μm pixels or smaller.

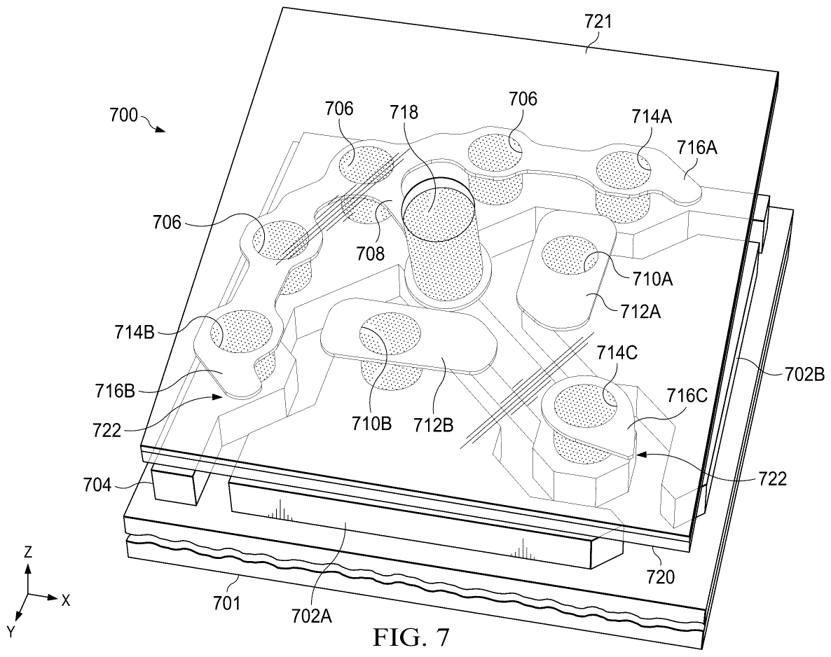

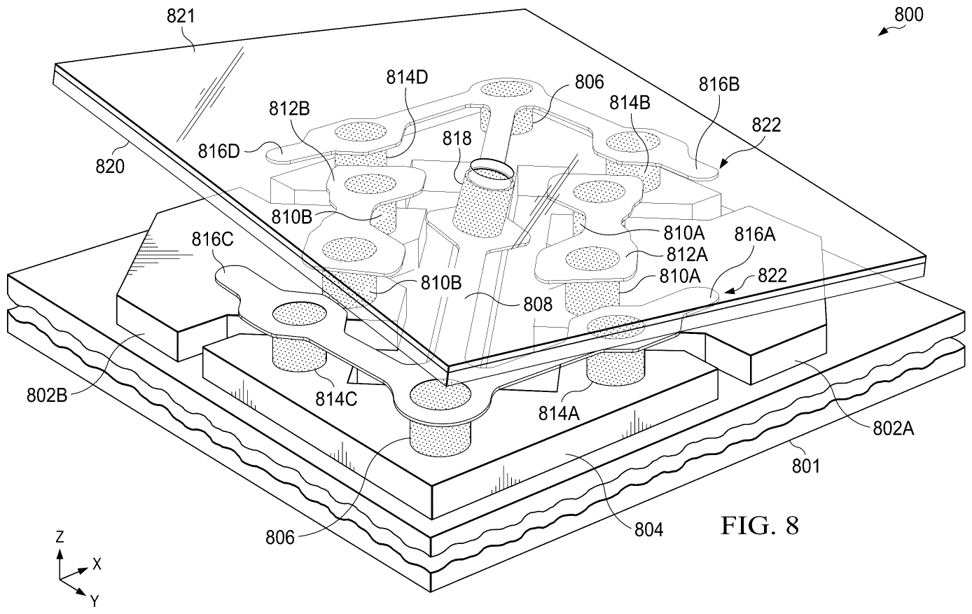

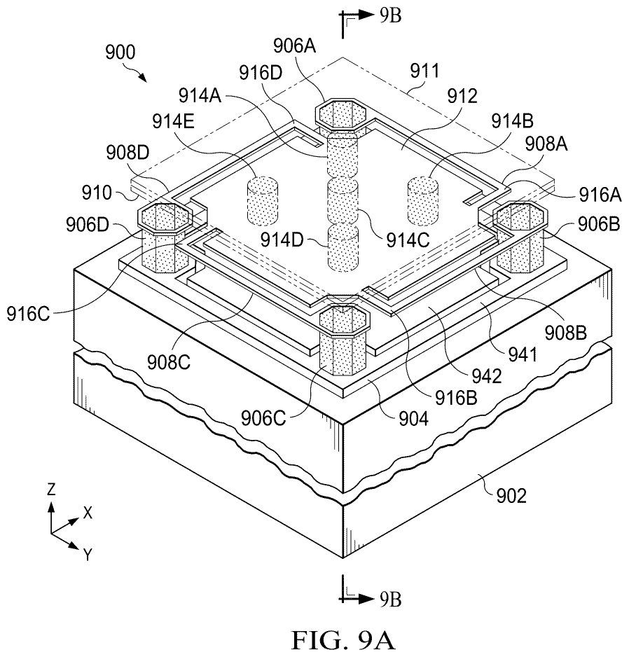

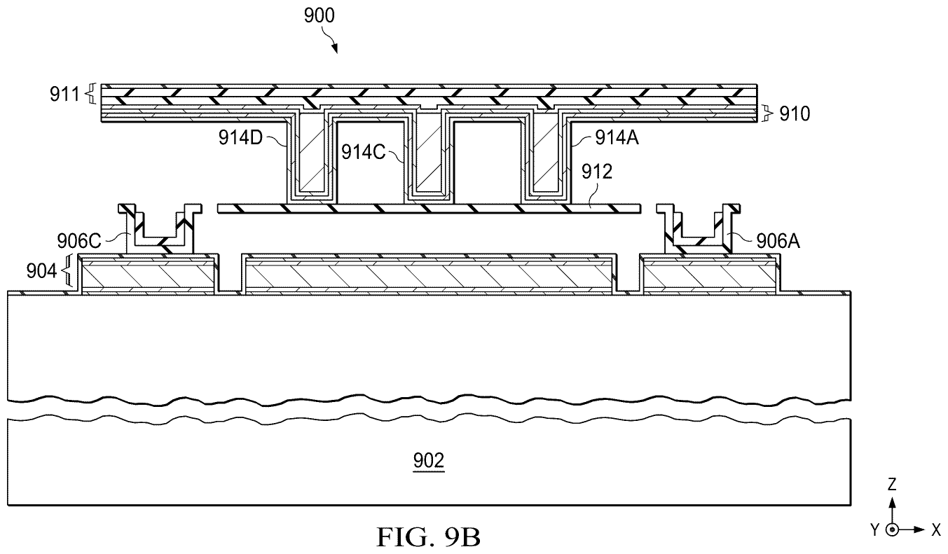

In some examples, the MEMS device 500 may be part of a single spring tip pixel as in FIG. 6. In other examples, the MEMS device 500 may be part of a tilt and roll pixel (TRP) element as in FIG. 7. In other examples, the MEMS device 500 may be part of a dual spring tip pixel as in FIG. 8. In other examples, the MEMS device 500 may be part of a PLM pixel as in FIG. 8 or FIGS. 9A and 9B.

Referring now to FIG. 6, a three-dimensional view of a MEMS device 600 configured as a single spring tip pixel is shown. As shown, the MEMS device 600 includes a base 601, hinge vias 606, first electrode vias 610A, second electrode vias 610B (collectively electrode vias 610), a first spring tip via 614A, a second spring tip via 614B, a mirror via 618, a mirror 620, a dielectric stack 621, an electrode layer 622, a hinge layer 624, and a mirror layer 626. While FIG. 6 is a three-dimensional view of MEMS device 600 with mirror 620 and dielectric stack 621 in a tilted position, the view in previously-described FIG. 4O of MEMS device 400 may effectively be considered a cross-sectional view of MEMS device 600 with the mirror 620 and dielectric stack 621 in a non-tilted position.

In the example of FIG. 6, the base 601 is split to represent that its thickness may vary. The base 601 may include circuitry to control different states of the MEMS device 600 responsive to received data. In some examples, the base 601 includes memory cells under the pixels. The electrode layer 622 is an example of the electrode layer 506 in FIG. 5. In some examples, the hinge vias 606, the first electrode vias 610A, the second electrode vias 610B, the first spring tip via 614A, and the second spring tip via 614B are examples of the via(s) 512 in FIG. 5. The mechanical layer 624 is an example of the mechanical layer 508 in FIG. 5. In some examples, the mirror via 618 is an example of the via(s) 514 in FIG. 5. The mirror layer 626, including mirror 620, is an example of the movable element(s) layer 510 in FIG. 5.

In the example of FIG. 6, the electrode layer 622 includes a first address electrode 602A, a second address electrode 602B, and a bias electrode 604 spaced from the first and second address electrodes 602A and 602B. The first address electrode 602A and the second address electrode 602B are examples of “bottom” electrodes that are part of one or more CMOS cells, and are examples of electrodes of the electrode layer 506 in FIG. 5. In some examples, there are two of the hinge vias 606, two of the first electrode vias 610A, two of the second electrode vias 610B, one first spring tip via 614A, one second spring tip via 614B, and one mirror via 618. In other examples, the number of hinge vias 606, the number of first electrode vias 610A, the number of second electrode vias 610B, the number of first spring tip vias 614A, the number of second spring tip vias 614B, and/or the number of mirror vias 618 may vary.

In the example of FIG. 6, the mechanical layer 624 includes a torsion hinge 608, a first raised electrode 612A, a second raised electrode 612B, a first spring tip 616A, and a second spring tip 616B. The first raised electrode 612A and the second raised electrode 612B are part of a hinge layer, and are examples of portions of the electrode layer 506 in FIG. 5. In other examples, the mechanical layer 624 may include multiple torsion hinges 608, multiple first raised electrodes 612A, multiple second raised electrodes 612B, multiple first spring tips 616A, and/or multiple second spring tips 616B. In the example of FIG. 6, the mirror layer 626 includes mirror 620. In other examples, the mirror layer 626 may include multiple mirrors 620. The mirror 620 includes a dielectric stack 621. The dielectric stack 621, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 621 may include two or more sets of alternating layers of high and low index of refraction dielectrics, similar to the dielectric stack 124 shown in FIG. 1C.

As shown, the position of the mirror 620 is tilted. In an example SLM, the position of the mirror 620 switches between different tilted positions responsive to received data, control voltages applied to the first address electrode 602A, the second address electrode 602B, and the bias electrode 604 responsive to received data, and movement of the torsion hinge 608 and mirror 620 responsive to application of the control voltages.

In the example of FIG. 6, the mirror 620 is in a first position, in which the mirror 620 contacts the second spring tip 616B responsive to control voltages applied to the first address electrode 602A, the second address electrode 602B, and the bias electrode 604. To change the position of the mirror 620 to another position (e.g., with the mirror 620 contacting the first spring tip 616A), updated control voltages are applied to the first address electrode 602A, the second address electrode 602B, and/or the bias electrode 604.

Without limitation, the MEMS device 600 may be used to form a pixel of a SLM of a display system. Example pixel sizes that may benefit from the MEMS device 600 include 9 μm pixels, 6 μm pixels, 5.4 μm pixels, 5.0 μm pixels, 4.5 μm pixels, 4.0 μm pixels, 3.6 μm pixels, 2.7 μm pixels, or other pixel dimensions. For the example pixel sizes, pixel pitch (side-to-side size) is used, and square pixels are assumed.

FIG. 7 shows a MEMS device 700 as an example of a TRP pixel (sometimes referred to as a “cantilever” pixel). In the example of FIG. 7, the MEMS device 700 includes a base 701, a first address electrode 702A, a second address electrode 702B, a bias electrode 704, spring tip vias 714A to 714C, a first electrode via 710A, a second electrode via 710B, hinge vias 706, a cantilever hinge 708, spring tips 716A to 716C, a first raised electrode 712A, a second raised electrode 712B, a mirror via 718, and a mirror 720. The base 701 is an example of the base 504 in FIG. 5. The first address electrode 702A, the second address electrode 702B, and the bias electrode 704 are example components of the electrode layer 506 in FIG. 5. The spring tip vias 714A to 714C, the first electrode via 710A, the second electrode via 710B, and the hinge vias 706 are examples of the via(s) 512 in FIG. 5. The cantilever hinge 708, the spring tips 716A to 716C, the first raised electrode 712A, and the second raised electrode 712B are example components of the mechanical layer 508 in FIG. 5. The mirror via 718 is an example of the via(s) 514 in FIG. 5. The mirror 720 is an example component of the movable element(s) layer 510 in FIG. 5. The mirror 720 includes a dielectric stack 721. The dielectric stack 721, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 721 may include two or more sets of alternating layers of high and low index of refraction dielectrics, similar to the dielectric stack 124 shown in FIG. 1C.

As shown, the position of the mirror 720 is tilted towards the spring tips 716B and 716C, which may be an on position for the mirror 720. In an example SLM, the position of the mirror 720 switches between different tilted positions (e.g., an on position in which the mirror 720 contacts spring tips 716B and 716C, and an off position in which the mirror 720 contacts the spring tips 716A and 716C) responsive to received data, control voltages applied to the first address electrode 702A, the second address electrode 702B, and the bias electrode 704 responsive to received data, and movement of the cantilever hinge 708 and mirror 720 responsive to application of the control voltages.

More particularly, in the example of FIG. 7, the mirror 720 is in a first position, in which the mirror 720 contacts the spring tips 716B and 716C at contact points 722 responsive to control voltages applied to the first address electrode 702A, the second address electrode 702B, and the bias electrode 704. To change the position of the mirror 720 to another position (e.g., the mirror 720 may contact the spring tips 716A and 716B), updated control voltages are applied to the first address electrode 702A, the second address electrode 702B, and/or the bias electrode 704.

Without limitation, the MEMS device 700 may be used to form a TRP pixel of a SLM of a display system. Example pixel sizes that may benefit from the MEMS device 700 include 6 μm pixels, 5.5 μm pixels, 5.0 μm pixels, 4.5 μm pixels, 4.0 μm pixels, 3.6 μm pixels, 2.7 μm pixels, or smaller pixels. For the example pixel sizes, pixel pitch (side-to-side size) is used, and square pixels are assumed.

In FIG. 8, a MEMS device 800 is an example of a dual spring tip pixel. In the example of FIG. 8, the MEMS device 800 includes a base 801, a first address electrode 802A, a second address electrode 802B, a bias electrode 804, spring tip vias 814A, 814B, 814C, and 814D, first electrode vias 810A, second electrode vias 810B, hinge vias 806, a torsion hinge 808, spring tips 816A to 816D, a first raised electrode 812A, a second raised electrode 812B, a mirror via 818, and a mirror 820. The base 801 is an example of the base 504 in FIG. 5. The first address electrode 802A, the second address electrode 802B, and the bias electrode 804 are example components of the electrode layer 506 in FIG. 5. The spring tip vias 814A, 814B, 814C, and 814D, the first electrode vias 810A, the second electrode vias 810B, and the hinge vias 806 are examples of the via(s) 512 in FIG. 5. The torsion hinge 808, the spring tips 816A to 816D, the first raised electrode 812A, and the second raised electrode 812B are example components of the mechanical layer 508 in FIG. 5. The mirror via 818 is an example of the via(s) 514 in FIG. 5. The mirror 820 is an example component of the movable element(s) layer 510 in FIG. 5. The mirror 820 includes a dielectric stack 821. The dielectric stack 821, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 821 may include two or more sets of alternating layers of high and low index of refraction dielectrics, similar to the dielectric stack 124 shown in FIG. 1C.

As shown, the position of the mirror 820 is tilted towards the spring tips 816A and 816B, which may be an on position for the mirror 820. In an example SLM, the position of the mirror 820 switches between different tilted positions (e.g., an on position in which the mirror 820 contacts spring tips 816A and 816B, and an off position in which the mirror 820 contacts the spring tips 816C and 816D) responsive to: received data; control voltages applied to the first address electrode 802A, the second address electrode 802B, and the bias electrode 804 responsive to received data, and movement of the torsion hinge 808 and mirror 820 responsive to application of the control voltages.

More particularly, in the example of FIG. 8, the mirror 820 is in a first position, in which the mirror 820 contacts the spring tips 816A and 816B at contact points 822 responsive to control voltages applied to the first address electrode 802A, the second address electrode 802B, and the bias electrode 804. To change the position of the mirror 820 to another position (e.g., the mirror 820 may contact the spring tips 816C and 816D), updated control voltages are applied to the first address electrode 802A, the second address electrode 802B, and/or the bias electrode 804.

Without limitation, the MEMS device 800 may be used to form a dual spring tip pixel of a SLM of a display system. Example pixel sizes that may benefit from the MEMS device 800 may range from 16 μm pixels down to 2.7 μm pixels or smaller.

In FIGS. 9A and 9B, a MEMS device 900 is an example of a phase light modulator (PLM) or related pixel. The MEMS device 900 includes a base 902, bottom electrode 904, support vias 906A, 906B, 906C, and 906D (sometimes referred to collectively as support vias 906 herein), hinges 908A, 908B, 908C, and 908D (sometimes referred to collectively as hinges 908 herein), mirror plate 910, top plate 912, and mirror vias 914A, 914B, 914C, 914D, and 914E (sometimes referred to collectively as mirror vias 914 herein). The base 902 is an example of the base 504 in FIG. 5. The bottom electrode 904 is an example component of the electrode layer 506 in FIG. 5. The bottom electrode 904 may include different bits which are electrically separated but part of the same bottom electrode 904. FIG. 9A, for example, shows a first bit 941 of the bottom electrode 904. In some examples, there are additional bottom electrode bits under the mirror plate 910 (not shown in FIG. 9A). FIG. 9A also shows a mirror bias routing element 942 of the bottom electrode 904, which is electrically connected to the hinges 908 and the mirror plate 910. The bottom electrode 904 also includes a series of nested electrodes which are hidden from the views of FIGS. 9A and 9B and are thus not shown.

The support vias 906 are examples of the via(s) 512 in FIG. 5. The hinges 908A, 908B, 908C, and 908D (sometimes referred to collectively as hinges 908 herein) and top plate 912 are example components of the mechanical layer 508 in FIG. 5. The mirror vias 914 are examples of the via(s) 514 in FIG. 5. The mirror plate 910 is an example component of the movable element(s) layer 510 in FIG. 5. The mirror plate 910 includes a dielectric stack 911. The dielectric stack 911, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 911 may include two or more sets of alternating layers of high and low index of refraction dielectrics, similar to the dielectric stack 124 shown in FIG. 1C.

In some examples, the support vias 906, the hinges 908, the mirror plate 910, the top plate 912, and the mirror vias 914 may be aluminum alloys. In the example of FIG. 9, the base 902 is split to represent its thickness may vary. In some examples, the base 902 includes a CMOS memory array, such as a static random access memory (SRAM) array. Bottom electrode 904 is also referred to as an electrode structure. In some examples, the bottom electrode 904 includes four segments (e.g., four electrodes) and a bias electrode. The four electrodes may be individually addressed to provide sixteen discrete positions for mirror plate 910. Support vias 906 couple the bias electrode portion of bottom electrode 904 to hinges 908. Each of the hinges 908 is coupled to an outside edge of a support via 906, away from the center of top plate 912. When hinges 908 are coupled to the center of a support via 906, top plate 912 can be relatively smaller. In the example of FIGS. 9A and 9B, top plate 912 is relatively larger. A larger top plate allows for more electrostatic force to be created between bottom electrode 904 and top plate 912. The hinges 908 are also coupled to top plate 912. In addition, each hinge 908 has a 90 degree turn 916A, 916B, 916C, and 916D, (sometimes referred to collectively as turns 916) where the hinge 908 couples to top plate 912. The turns 916 provide flexibility for a hinge 908, so the hinge 908 may flex if a voltage difference exists between top plate 912 and bottom electrode 904, which allows top plate 912 to move up and down relative to bottom electrode 904. Mirror plate 910 is coupled to top plate 912 by way of mirror vias 914 (shown as dashed lines in FIGS. 9A and 9B).

In operation, a bias voltage is applied to support vias 906, hinges 908, top plate 912, and mirror plate 910, which are coupled to one another and therefore are each at the same bias voltage. The bias voltage may be 0 volts (V), in one example, or could be another voltage, in another example. Voltages greater than 0V are applied to some combination of the four segments of bottom electrode 904. The voltage difference between the bottom electrode 904 and the top plate 912 creates an electrostatic force that pulls the top plate 912 down toward bottom electrode 904. Mirror plate 910 moves down with top plate 912 as well. The movement up and down of top plate 912 and mirror plate 910 (with respect to bottom electrode 904) modulates the phase of the light that is reflected by mirror plate 910. Voltages are applied to different combinations of the segments of bottom electrode 904 to move mirror plate 910 and top plate 912 to different vertical positions. Moving the mirror plate 910 up and down at a high frequency modulates the phase of the reflected light, and images are produced using an array of mirror plates 910.

In some examples, the MEMS device 900 has a 4-bit electrode design for bottom electrode 904, which provides up to sixteen discrete vertical positions for mirror plate 910. With the MEMS device 900, each hinge 908 connects tangentially to an edge, instead of a center, of a support via 906. By connecting to an edge of a support via 906, top plate 912 is larger, and more usable area beneath top plate 912 is available for bottom electrode 904. A larger bottom electrode 904 allows for more electrostatic force to be created between bottom electrode 904 and top plate 912, which is useful for increasing the amount of vertical movement of top plate 912 and mirror plate 910.

Without limitation, the MEMS device 900 may be used to form a pixel of a PLM of a display system. Example pixel sizes that may benefit from the MEMS device 900 may range from 16 μm pixels down to 2.7 μm pixels or smaller.

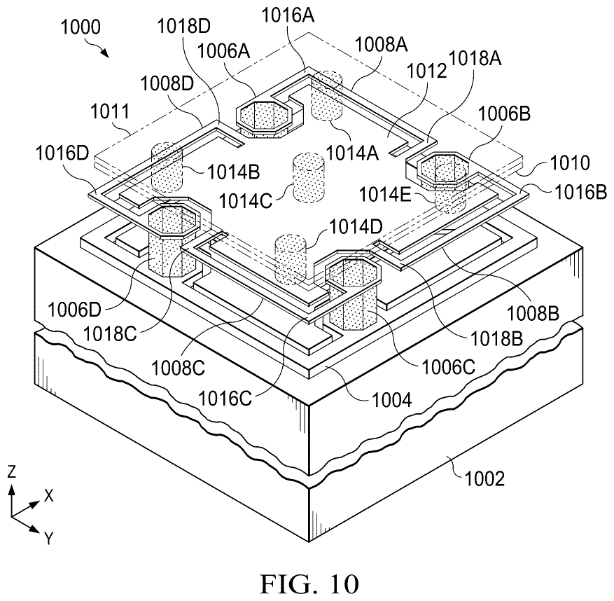

In FIG. 10, a MEMS device 1000 is an example of another PLM or related pixel. In some examples, the MEMS device 1000 has a 4-bit electrode design. The MEMS device 1000 includes a base 1002, bottom electrode 1004, support vias 1006A, 1006B, 1006C, and 1006D (sometimes referred to collectively as support vias 1006 herein), hinges 1008A, 1008B, 1008C, and 1008D (sometimes referred to collectively as hinges 1008 herein), mirror plate 1010, top plate 1012, and mirror vias 1014A, 1014B, 1014C, 1014D, and 1014E (sometimes referred to collectively as mirror vias 1014 herein). The base 1002 is an example of the base 504 in FIG. 5. The bottom electrode 1004 is an example component of the electrode layer 506 in FIG. 5. The support vias 1006 are examples of the via(s) 512 in FIG. 5. The hinges 1008A, 1008B, 1008C, and 1008D (sometimes referred to collectively as hinges 1008 herein) and top plate 1012 are example components of the mechanical layer 508 in FIG. 5. The mirror vias 1014 are examples of the via(s) 514 in FIG. 5. The mirror plate 1010 is an example component of the movable element(s) layer 510 in FIG. 5. The mirror plate 1010 includes a dielectric stack 1011. The dielectric stack 1011, similar to the dielectric stack 104 shown in FIG. 1A, may include a first dielectric layer having an index of refraction n₁ and a second dielectric layer having an index of refraction n₂, where n₂ is greater than n₁. Alternatively, the dielectric stack 1011 may include two or more sets of alternating layers of high and low index of refraction dielectrics, similar to the dielectric stack 124 shown in FIG. 1C.

In some examples, the support vias 1006, the hinges 1008, the mirror plate 1010, the top plate 1012, and the mirror vias 1014 may be aluminum alloys. In the example of FIG. 10, the base 1002 is split to represent its thickness may vary. In some examples, the base 1002 includes a CMOS SRAM memory array. Bottom electrode 1004 is also referred to as an electrode structure. In some examples, the bottom electrode 1004 includes four segments that are individually addressed to provide up to sixteen discrete positions for mirror plate 1010. Bottom electrode 1004 may also include a bias electrode. Support vias 1006 couple the bias electrode portion of bottom electrode 1004 to hinges 1008. Each of the hinges 1008 is coupled to an outside edge of a support via 1006, away from the center of top plate 1012 (instead of being coupled to the center of a support via 1006). The hinges 1008 are also coupled to top plate 1012. In addition, each of the hinges 1008 has two 90 degree turns: one turn at a corner of the MEMS device 1000 (turns 1016A, 1016B, 1016C, and 1016D, collectively turns 1016) and one turn where the hinge couples to top plate 1012 (turns 1018A, 1018B, 1018C, and 1018D, collectively turns 1018). The turns 1016 and 1018 provide flexibility for a hinge 1008, so the hinge 1008 may flex if a voltage difference exists between top plate 1012 and bottom electrode 1004, which allows top plate 1012 to move up and down relative to bottom electrode 1004. Two turns in each hinge 1008 may provide more relief of hinge stresses than one turn in each hinge 1008. Mirror plate 1010 is coupled to top plate 1012 by way of mirror vias 1014 (shown as dashed lines in FIG. 10).

The MEMS device 1000 of FIG. 10 operates similarly to the MEMS device 900 of FIGS. 9A and 9B. In summary, the voltage differential between the bottom electrode 1004 and the top plate 1012 creates an electrostatic force that pulls the top plate 1012 down toward bottom electrode 1004. Mirror plate 1010 moves down with top plate 1012 as well. The movement up and down of mirror plate 1010 modulates the phase of the light that is reflected by mirror plate 1010 to produce images.

In some examples, the bottom electrode 1004 of the MEMS device 1000 has a 4-bit electrode design to provide up to sixteen discrete vertical positions for mirror plate 1010. In different examples, the MEMS device 1000 may be configured for a different number of bits.

With the MEMS device 1000, each hinge 1008 couples to top plate 1012 on an adjacent side from a support via 1006 that each respective hinge couples to. For example, hinge 1008A couples to support via 1006A. Hinge 1008A couples to top plate 1012 on a side of top plate 1012 that is adjacent to the side of top plate 1012 where support via 1006A is located. The hinge design shown for the MEMS device 1000 may provide increased hinge compliance and additional relief of hinge stresses for better thermal stability compared to the MEMS device 900. Also, the MEMS device 1000 allows alternate locations for support vias 1006 compared to the MEMS device 900.

Without limitation, the MEMS device 1000 may be used to form a pixel of a PLM of a display system. Example pixel sizes that may benefit from the MEMS device 1000 may range from 16 μm pixels down to 2.7 μm pixels or smaller.

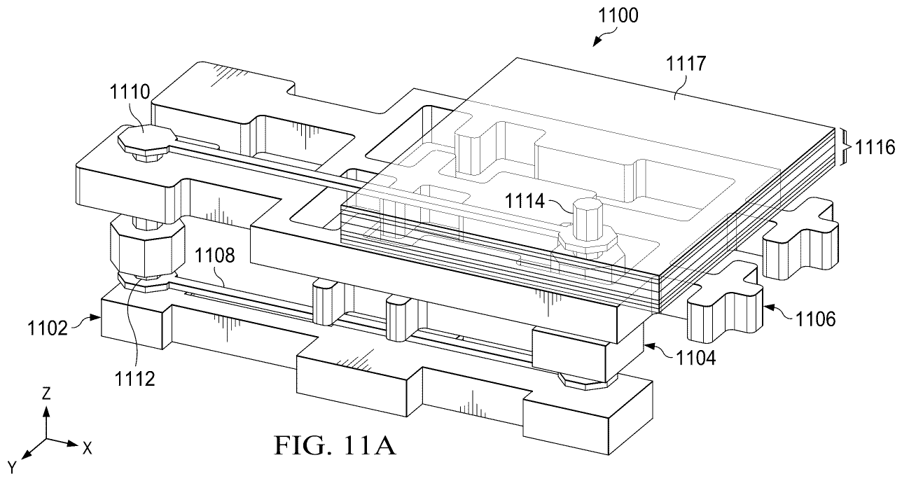

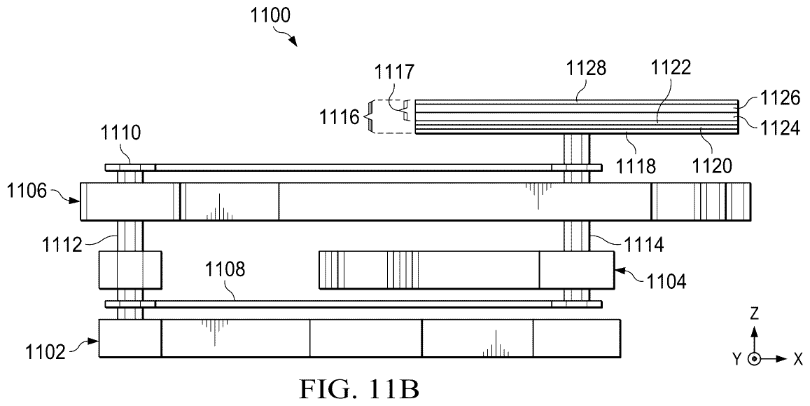

FIGS. 11A and 11B are respective three-dimensional and cross-sectional views of a micromirror device 1100 in accordance with one or more examples of the present disclosure. In this example, the micromirror device 1100 is for a MEMS device which utilizes comb-drive MEMS actuators, and is an example of a PLM. The micromirror device 1100 includes a base plate 1102, a yoke 1104, a stator 1106, a first spring 1108, a second spring 1110, a first actuator structure 1112, a second actuator structure 1114, and a mirror 1116 including a dielectric mirror stack 1117. In some examples, the base plate 1102 is an example of the base 504 in FIG. 5. In some examples, the yoke 1104 and the stator 1106 are example components of the electrode layer 506 in FIG. 5. In some examples, the first spring 1108, the second spring 1110, the first actuator structure 1112 and the second actuator structure 1114 are example components of the mechanical layer 508 in FIG. 5. In some examples, the mirror 1116 is an example component of the movable element(s) layer 510 in FIG. 5.

As shown in detail in the cross-sectional view of FIG. 11B, the mirror 1116 includes a bottom mirror metal layer 1118, an alloy layer 1120 (sometimes referred to as stress control layer 1120), a top mirror metal layer 1122, a first dielectric layer 1124, a second dielectric layer 1126 and a third dielectric layer 1128 (sometimes referred to as protective layer 1128). The bottom mirror metal layer 1118 and the top mirror metal layer 1122 may be formed of Al, while the alloy layer 1120 may be formed of TiAl₃. The first dielectric layer 1124 may be formed of SiO₂, while the second dielectric layer 1126 may be formed of TiO₂. The third dielectric layer 1128 may be formed of Al₂O₃. The first dielectric layer 1124, the second dielectric layer 1126 and the third dielectric layer 1128 provide the dielectric mirror stack 1117 for the micromirror device 1100, where the first dielectric layer 1124 and the second dielectric layer 1126 have respective different refraction indices (e.g., the first dielectric layer 1124 has a lower refraction index than the second dielectric layer 1126).

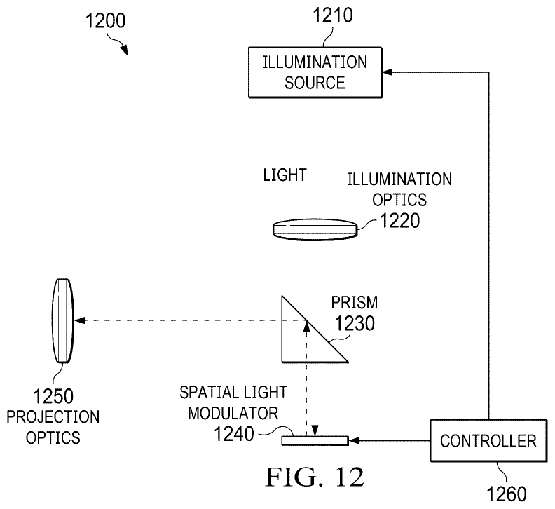

FIG. 12 is a block diagram of a projection system 1200 with an SLM in accordance with one or more examples of the present disclosure. As shown, the projection system 1200 includes an illumination source 1210, illumination optics 1220, a prism 1230, an SLM 1240, projection optics 1250, and a controller 1260.

Light from illumination source 1210 passes through illumination optics 1220 and prism 1230 to the SLM 1240, which spatially modulates the light. SLM 1240 may include any suitable SLM such as, for example, a digital micromirror device (DMD). SLM 1240 can be configured with a dielectric stack (e.g., dielectric layers 214 and 216 in FIG. 2), a dielectric layer providing protective functionality (e.g., dielectric layer 218 in FIG. 2), and/or an alloy layer providing stress control functionality (e.g., alloy layer 208 in FIG. 2) as described herein according to one or more examples.

Projection optics 1250 receive the light from SLM 1240 via prism 1230 and focuses the spatially-modulated light onto a light receiving medium, e.g., a projection surface (not expressly shown). Controller 1260 may be coupled to SLM 1240 to control the operation of the SLM 1240 to produce images and to the illumination source 1210 to control the illumination source 1210. Controller 1260 may receive digital data based on the images to be produced by SLM 1240 and controls the SLM 1240 based on the digital data.

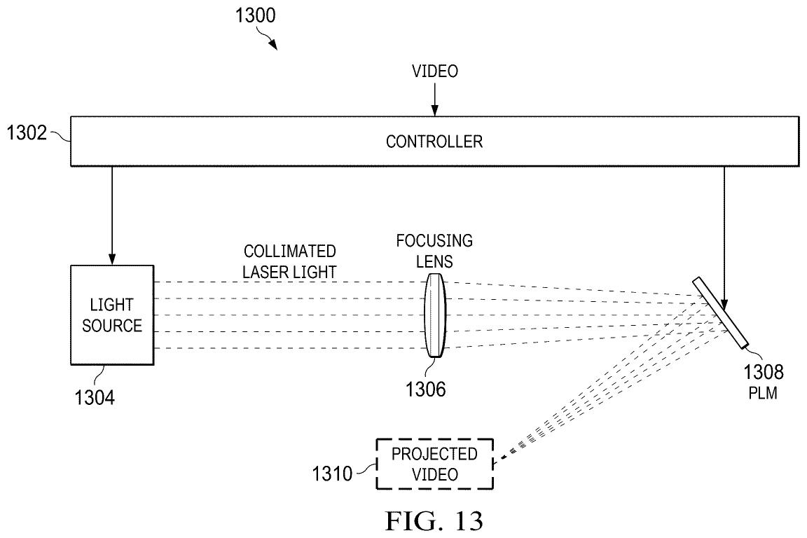

FIG. 13 is a block diagram of a projection system 1300 with a PLM in accordance with one or more examples of the present disclosure. As shown, the projection system 1300 includes a controller 1302, a light source 1304, a focusing lens 1306, and a PLM 1308. In the example of FIG. 13, the controller 1302 is configured to receive video data, generate zone brightness data responsive to the video data or related image analysis results, obtain a baseline hologram, determine a sub-hologram for each of a plurality of brightness zones indicated by the zone brightness data responsive to the baseline hologram and respective brightness zone transforms, combine the sub-holograms to produce and output the target hologram. The controller 1302 is also configured to provide control signals to the light source 1304 and the PLM 1308.

The light source 1304 is configured to receive one or more control signals from the controller 1302 and generate collimated laser light that is provided to the focusing lens 1306 which focuses the collimated laser light. The PLM 1308 is configured to receive one or more control signals from the controller 1302 and receive the focused collimated laser light from the focusing lens 1306, and phase-modulate and reflect the focused collimated laser light to generate a projected video 1310. PLM 1308 can be configured with a dielectric stack (e.g., dielectric layers 214 and 216 in FIG. 2), a dielectric layer providing protective functionality (e.g., dielectric layer 218 in FIG. 2), and/or an alloy layer providing stress control functionality (e.g., alloy layer 208 in FIG. 2) as described herein according to one or more examples.

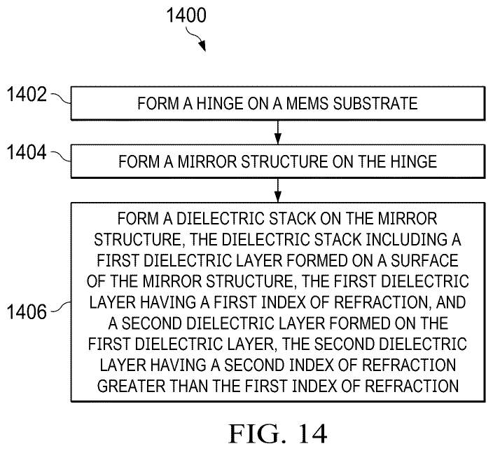

FIG. 14 is a flow diagram of a methodology 1400 for fabricating a MEMS device in accordance with one or more examples of the present disclosure. In step 1402, a hinge is formed on a MEMS substrate. In step 1404, a mirror structure is formed on the hinge. In step 1406, a dielectric stack is formed on the mirror structure. The dielectric stack includes a first dielectric layer formed on a surface of the mirror structure, the first dielectric layer having a first index of refraction, and a second dielectric layer formed on the first dielectric layer, the second dielectric layer having a second index of refraction greater than the first index of refraction.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A device, comprising:
one or more layers of a microelectromechanical system (MEMS) structure; and
a dielectric stack over the one or more layers, the dielectric stack including:
a first dielectric layer having a first index of refraction; and
a second dielectric layer having a second index of refraction different than the first index of refraction.

2. The device of claim 1, wherein the first dielectric layer is on one of the one or more layers, the second dielectric layer is on the first dielectric layer, and the first index of refraction is less than the second index of refraction.

3. The device of claim 1, wherein the first dielectric layer includes silicon oxide and the second dielectric layer includes titanium oxide.

4. The device of claim 1, further comprising a third dielectric layer on the dielectric stack.

5. The device of claim 4, wherein the third dielectric layer includes aluminum oxide.

6. The device of claim 1, further comprising an alloy layer positioned within the one or more layers.

7. The device of claim 6, wherein the alloy layer includes titanium aluminide.

8. The device of claim 1, wherein the one or more layers include:
a substrate;
a hinge over the substrate; and
a mirror structure supported by the hinge;
wherein the dielectric stack is positioned on the mirror structure.

9. The device of claim 8, wherein the mirror structure is configurable to modulate a spatial attribute of a light beam.

10. The device of claim 8, wherein the mirror structure is configurable to modulate a phase attribute of a light beam.

11. A device, comprising:
a MEMS substrate;
a hinge over the MEMS substrate;
a mirror structure supported by the hinge; and
a dielectric stack over the mirror structure, the dielectric stack including:
a first dielectric layer having a first index of refraction; and
a second dielectric layer having a second index of refraction greater than the first index of refraction.

12. The device of claim 11, wherein the first dielectric layer is on the mirror structure and includes silicon oxide, and the second dielectric layer is on the first dielectric layer and includes titanium oxide.

13. The device of claim 11, further comprising a third dielectric layer on the dielectric stack, wherein the third dielectric layer includes aluminum oxide.

14. The device of claim 11, further comprising an alloy layer positioned within the mirror structure, wherein the alloy layer includes titanium aluminide.

15. A method of manufacturing a device, comprising:
forming a hinge on a MEMS substrate;
forming a mirror structure on the hinge; and
forming a dielectric stack on the mirror structure, the dielectric stack including a first dielectric layer formed on a surface of the mirror structure, the first dielectric layer having a first index of refraction, and a second dielectric layer formed on the first dielectric layer, the second dielectric layer having a second index of refraction greater than the first index of refraction.

16. The method of claim 15, wherein the first dielectric layer includes silicon oxide and the second dielectric layer includes titanium oxide.

17. The method of claim 15, further comprising:
forming a third dielectric layer on the dielectric stack, wherein the third dielectric layer includes aluminum oxide.

18. The method of claim 15, wherein forming the mirror structure further comprises:
forming an alloy layer within the mirror structure, wherein the alloy layer includes titanium aluminide.

19. The method of claim 15, wherein the forming of the mirror structure and the forming of the dielectric stack is performed at least in part during an integrated in-situ process.

20. The method of claim 19, wherein the integrated in-situ process further comprises:
depositing the first dielectric layer;
depositing the second dielectric layer;
patterning a mask structure; and
performing a multi-step etch of the first dielectric layer and the second dielectric layer using two or more etch chemistries.
